(19) United States
(12) Patent Application Publication
(10) Pub. No.: US 2026/0280229 A1
(43) Pub. Date: Sep. 17, 2026

(54) MULTIPLE CAVITY VERTICAL-CAVITY SURFACE EMITTING LASER SYSTEM

(71) Applicant: Jack Lee Jewell, Boulder, CO (US)

(72) Inventor: Jack Lee Jewell, Boulder, CO (US)

(21) Appl. No.: 19/566,769

(22) Filed: Mar. 13, 2026

Related U.S. Application Data
(60) Provisional application No. 63/773,075, filed on Mar. 17, 2025.

(51) Int. Cl. H01S 5/10; H01S 5/125; H01S 5/183

(52) U.S. Cl. CPC H01S 5/1021; H01S 5/125; H01S 5/18361

(57) ABSTRACT

Implementations disclosed herein provide a two-cavity distributed-feedback (2CDFB) laser device, a two-cavity vertical-cavity surface-emitting laser (2CVCSEL), and a coupled-cavity semiconductor laser. The 2CDFB may include a first cavity and a second cavity separated by an intercavity distributed Bragg reflector (DBR) configured as a frequency-tuning element. The 2CVCSEL may include a first optical cavity and a second optical cavity separated by an intercavity DBR functioning as a frequency-control element. The coupled-cavity semiconductor laser may include a first optical cavity and a second optical cavity separated by a coupling region configured to support at least two longitudinal modes.

The present application is based on and claims the benefit of priority to U.S. Provisional Patent Application No. 63/773,075, entitled “Multiple Cavity Laser” and filed on Mar. 17, 2025, which is specifically incorporated by reference herein for all that it discloses or teaches.

### BACKGROUND

Demand for higher-bandwidth interconnections for data communication, supercomputers, and artificial intelligence (AI) computers, creates a need for higher modulation speeds of light sources. The latest solutions incorporate various semiconductor lasers technologies, including Distributed-Feedback (DFB) lasers and vertical-cavity surface-emitting lasers (VCSELs). Organizations such as IEEE standardizes data rates per line, i.e., the direct electrical-to-optical conversion rate without optical or spatial multiplexing, for line rates >200 gigabits per second (Gb/s). However, advanced technology solutions require even higher speeds such as >400 Gb/s and even >800 Gb/s.

### SUMMARY

An implementation disclosed herein provides a two-cavity distributed-feedback (2CDFB) laser device. The 2CDFB includes a first cavity and a second cavity separated by an intercavity distributed Bragg reflector (DBR) configured as a frequency-tuning element, a first outer DBR and a second outer DBR each configured to define a quality-factor (Q) tuning function, the first cavity and the second cavity each having an optical thickness that is nominally an integral multiple of half-waves, and a pair of resonances separated by a photon-photon resonance (PPR) frequency selected to enhance modulation response at data rates exceeding 400 Gb/s. As used herein, the modulation response is the response of the modulated optical output power (or electric field) to the modulated electrical power (or electric field). The modulation bandwidth of a laser is where its small-signal modulation response falls below −3 dB power (or −6 dB field). Converting these quantities to bit rate, e.g. 400 Gigabit/sec, is not straightforward or constant due to varying quantities of “overhead,” “correction,” standardized formatting, and more. Herein the term “400 Gb/s” includes bit rates of 448 Gb/s, possibly requiring more bits/s for more overhead, etc. These rates assume PAM4 (4-level) modulation. To support that requires at least NRZ (2-level) modulation at half that rate, e.g. >224 Gb/s. Ideally the modulation bandwidth would be half of the NRZ bit rate (the Nyquist frequency), i.e. ≥112 Gb/s. With electronic enhancements, a laser with a modulation bandwidth ~70% of the Nyquist frequency may be a successful source in a robust optical link. Thus, a 448 Gb/s link may be possible with a minimum modulation bandwidth of ~80 GHz.

An alternative implementation disclosed herein provides a two-cavity vertical-cavity surface-emitting laser (2CVCSEL). The 2CVCSEL includes a first optical cavity and a second optical cavity separated by an intercavity DBR functioning as a frequency-control element, a first outer DBR and a second outer DBR each comprising alternating high- and low-index quarter-wave layers, the first cavity and the second cavity each formed of GaAs-based material and having an optical thickness of nominally an integral multiple of half-waves, wherein the structure supporting two longitudinal modes separated by a photon-photon resonance frequency to enhance modulation bandwidth.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Other implementations are also described and recited herein.

### BRIEF DESCRIPTIONS OF THE DRAWINGS

In order that the present invention may be more clearly ascertained, some embodiments will now be described, by way of example, with reference to the following figures.

FIG. 1A illustrates an example physical/functional layout of a segmented multiple-cavity VCSEL.

FIG. 1B illustrates example laser emission spectra showing the narrowing of the wavelength difference with increasing temperature between the dominant DFB emission and the passive cavity.

FIG. 1C illustrates an example optical modulation-frequency-response spectrum for a small-signal modulated electrical input signal.

FIGS. 1D-1G illustrate example eye diagrams of the laser testing while employing various combinations of speed (Gbps) and temperature (centigrade).

FIG. 2 illustrates example reflectance spectra of three (3) different DFB structures.

FIG. 3 illustrates an example side view of a base structure of an example two cavity DFB structure.

FIG. 4 illustrates an example graph of transmittance vs wavelength for the two cavity DFB structure illustrated in FIG. 3.

FIG. 5a illustrates an example graph illustrating dependences of the frequency separation (PPR frequency) upon variations in the number of layers in the intercavity DBR and in the outer DBRs.

FIG. 5b illustrates an example graph illustrating relation between the peaks' FWHM and variations in the number of layers in the intercavity DBR and in the outer DBRs.

FIG. 5c illustrates an example graph illustrating how varying the cavity thicknesses affects both the modal (PPR) separation and the FWHM of the peaks.

FIG. 5d is a table illustrating the dependence upon cavity thickness of the modal separation, FWHM, and their ratio.

FIG. 6 illustrates an example plot of transmittance and reflectance corresponding to the graph illustrated in FIG. 5b.

FIGS. 7a-7c illustrate example graphs of intensity of standing waves in three different regions of the laser cavity structure.

FIG. 8a illustrates an example graph of ratio of the peak transmittances plotted vs the number of affected layers, for each of four extinction coefficients.

FIG. 8b illustrates an example graph of a scaled ratio, wherein the ratio used in FIG. 8a is multiplied by the peak transmittance of the advantaged mode.

FIG. 9 illustrates an example graph of simulated reflectance of the base design DFB structure, and a similarly-frequency-tuned structure which has a refractive-index difference between the layers of one (1) %.

FIG. 10 illustrates an example base structure of a VCSEL having multiple layers.

FIG. 11 illustrates an example spectrum of transmittance for the VCSEL disclosed in FIG. 10.

FIG. 12a illustrates an example graph of frequency separation (Av) for various number of quarter-wave layers relative to the base design.

FIG. 12b illustrates an example graph of wavelength separation (nm) for various number of outer DBR mirror layers relative to the base design.

FIG. 12c illustrates an example graph of wavelength separation (nm) for various cavity thickness levels.

FIG. 12d illustrates an example table illustrating the ratio of dLam/FWHM for various number of layers in the intercavity DBR.

FIGS. 13a-13c illustrate example direct transmittance spectra corresponding to the plotted data of FIGS. 12a-c.

FIGS. 14a-14c illustrate example intensity profiles in three (3) regions for two different modes, one at 939.776 nm and the other at 940.225 nm.

FIG. 15 illustrates example results of ratio of mode peak transmittance vs log 10 [k] in layer 74 for an example CVCSEL.

FIG. 16a illustrates dependence of the frequency separation (GHz) on slight changes in layer optical thicknesses for a 2CVCSEL.

FIG. 16b illustrates dependence of the frequency separation (GHz) on slight changes in layer optical thicknesses for two 2CDFB's.

FIG. 17 illustrates operational temperature and physical and/or optical thickness levels of various cavity regions at different current levels.

FIGS. 18a-18f illustrate example graphs of electric field intensity vs optical distance from medium for various implementations of a 2CVSEL.

FIG. 19 illustrates peak intensities in the 1st (top) cavity for two different modes at shorter-wavelength (first mode) and longer-wavelength (second mode), vs increases in thicknesses of the first (top) DBR and 1st (top) cavity in parts per 1,000, relative to the rest of the thicknesses.

FIG. 20 illustrates an example reflectance spectrum for an implementation of an 2CVSEL.

### DETAILED DESCRIPTIONS

The present invention will now be described in detail with reference to several embodiments thereof as illustrated in the accompanying drawings. In the following description, numerous specific details are set forth in order to provide a thorough understanding of embodiments of the present invention. It will be apparent, however, to one skilled in the art, that embodiments may be practiced without some or all of these specific details. In other instances, well known process steps and/or structures have not been described in detail in order to not unnecessarily obscure the present invention. The features and advantages of embodiments may be better understood with reference to the drawings and discussions that follow. Aspects, features and advantages of exemplary embodiments of the present invention will become better understood with regard to the following description in connection with the accompanying drawing(s). It should be apparent to those skilled in the art that the described embodiments of the present invention provided herein are illustrative only and not limiting, having been presented by way of example only. All features disclosed in this description may be replaced by alternative features serving the same or similar purpose, unless expressly stated otherwise. Therefore, numerous other embodiments of the modifications thereof are contemplated as falling within the scope of the present invention as defined herein and equivalents thereto. Hence, use of absolute and/or sequential terms, such as, for example, “will,” “will not,” “shall,” “shall not,” “must,” “must not,” “first,” “initially,” “next,” “subsequently,” “before,” “after,” “lastly,” and “finally,” are not meant to limit the scope of the present invention as the embodiments disclosed herein are merely exemplary. It should be noted that the terms “about”, “approximately”, “roughly” and the like may be employed. In general, these terms are intended to indicate that the value or range provided may vary by a set amount. Generally, the term “about” is intended to suggest a variation of plus or minus ten percent of the value provided. The terms “approximately” or “roughly” may indicate a value that is within one standard deviation of the provided value or range.

Demand for higher-bandwidth interconnections for data communication, supercomputers, and artificial intelligence (AI) computers, creates a need for higher modulation speeds of light sources. The latest solutions incorporate various semiconductor lasers technologies, including Distributed-Feedback (DFB) lasers and vertical-cavity surface-emitting lasers (VCSELs). Organizations, such as IEEE, standardizes data rates per line, i.e., the direct electrical-to-optical conversion rate without optical multiplexing for line rates >200 gigabits per second (Gb/s). However, advanced technology solutions require even higher speeds such as >400 Gb/s and even >800 Gb/s.

To achieve such higher data rates, advanced encoding method, known as pulse-amplitude-modulation 4-level (PAM4) technique uses four (4) levels of intensity modulation. Specifically, PAM4 devices may transmit data at twice the rate of binary-modulated data at the same base frequency. At a given modulation base frequency (MBF), e.g. 112 GHz, binary modulation (usually termed “non-return-to-zero,” or NRZ) can turn from off (0) to on (1) and back to off (0) in one cycle. Thus, a binary NRZ signal with a ~112 GHz MBF may transmit 224 Gb/s NRZ, and with PAM4, 448 Gb/s. Today's highest standardized rates are about half that. To double the data rate above PAM4 via PAM modulation would require 16 levels, i.e. PAM16, which is difficult due to noise and linearity of the electrical-to-optical (EO) conversion. A laser's modulation frequency is limited by many factors including carrier (electrons and holes) dynamics and electrical parasitics.

Multiple laser mode(s) with slightly different resonant frequencies can be created by a variety of means, including laterally adjacent cavities in close enough proximity to the main laser cavity for them to interact at the difference between the two frequencies, and/or combinations of frequencies for more than 2 modes. This frequency difference is basically the “beat frequency,” analogous to a sonic beat frequency for tones of different frequencies, in which the sonic amplitude changes between higher and lower at the beat frequency. Herein, the optical frequency difference between two modes is referred to as the PPR frequency. Modulation-speed enhancement (MSE) via PPR has been shown in both VCSELs and DFB lasers. Some demonstrations employ lateral coupling via side-by-side weakly coupled optical cavities. In VCSELs higher-order transverse modes within the cavity resonating at slightly higher frequencies than the fundamental mode, also enhance the modulation frequency, but are often subject to noise instabilities and require careful design.

Technology disclosed herein provides implementations of multiple-cavity DFBs (MCDFBs) and multiple-cavity VCSELs (MCVCSELs), having 2 (or more) cavities instead of the normal single-cavity design. This produces a laser with 2 (or more) longitudinal resonances spaced on the order of 100 GHz apart, e.g. 10 GHz to >1 THz. The design herein may be evaluated on optical thin-film evaluations with the Essential Macleod software package. As used herein, Essential Macleod is a 1-dimensional purely static purely optical evaluation; it may not include optical gain, electrical characteristics, carrier lifetimes, cavity response times, active modulation, or other laser properties. Nonetheless, the evaluation is very useful for evaluating the cavity resonances of DFBs and VCSELs, including modifications by adding cavities, introduction of absorption into selected portions of the structure, and other relevant features. Herein, at least some of said outer DBRs, cavities, and intercavity DBRs primarily comprise semiconductors comprising elements of the group including: Al, Ga, In, N, P, As, and Sb. Terms such as “GaAs based” may apply to structures comprising any or all elements of that group. At least one of outer DBRs may additionally comprise dielectric materials.

An implementation disclosed herein provides a two-cavity distributed-feedback (2CDFB) laser device. The 2CDFB includes a first cavity and a second cavity separated by an intercavity distributed Bragg reflector (DBR) configured as an architectural frequency-tuning element, a first outer DBR and a second outer DBR each configured to define a quality-factor (Q) tuning function, the first cavity and the second cavity each having an optical thickness that is an integral multiple of half-waves, wherein the structure supporting two longitudinal modes separated by a photon-photon resonance frequency to enhance modulation bandwidth.

An alternative implementation disclosed herein provides a two-cavity vertical-cavity surface-emitting laser (2CVCSEL). The 2CVCSEL includes a first optical cavity and a second optical cavity separated by an intercavity DBR functioning as an architectural frequency-tuning element, a first outer DBR and a second outer DBR each comprising alternating high- and low-index quarter-wave layers, the first cavity and the second cavity each formed of GaAs-based material and having an optical thickness of approximately an integral multiple of half-waves, wherein the structure supporting two longitudinal modes separated by a photon-photon resonance frequency to enhance modulation bandwidth.

Another alternative implementation disclosed herein provides a coupled-cavity semiconductor laser. The coupled-cavity semiconductor laser includes a first optical cavity and a second optical cavity separated by a coupling region configured to support at least two longitudinal modes, the cavities and coupling region being dimensioned such that the longitudinal modes are separated by a photon-photon resonance (PPR) frequency, and a longitudinal-mode-selective loss mechanism configured to suppress at least one of the longitudinal modes to stabilize single-mode operation while maintaining enhanced modulation response at the PPR frequency.

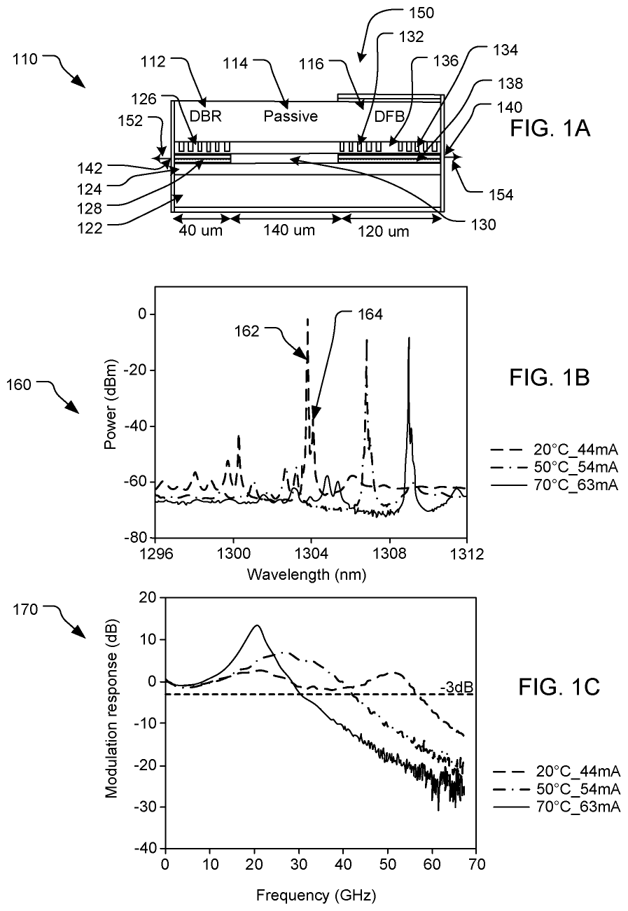

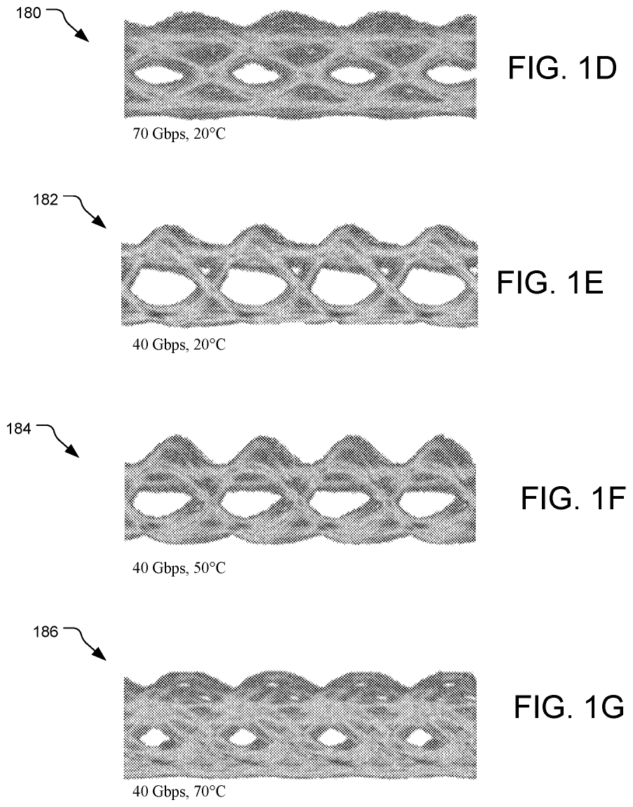

FIG. 1A illustrates a Prior Art DFB laser longitudinally coupled with an external passive cavity and an active DBR, to produce the desired MSE termed “external-passive-cavity DFB laser.” Specifically, FIG. 1A illustrates a physical/functional layout of a segmented external-passive-cavity DFB laser. 110. Specifically, external-passive-cavity DFB laser 110 includes a DFB laser device that has been longitudinally coupled with an external passive cavity. The external-passive-cavity DFB laser 110 includes a substrate 122, a low-index cladding layer DBR segment 112, a passive segment 114, and a DFB segment 116. In the illustrated implementation, these segments may have length of 40 μm, 140 μm, 120 μm, respectively. The DBR segment 112, a passive segment 114 may be added to the DFB segment 116 to produce a second resonance having a frequency 20-50 GHz separated from that of the DFB.

Specifically, the external-passive-cavity DFB laser 110 comprises a substrate 122 and a cladding layer 124. The DBR segment 112 may include etched ridges (grating-based DBR's) 126 used to tune quality factor, consistent with the role of outer DBRs in coupled-cavity resonance design, an active waveguide 128. The passive segment 114 may include a non-active waveguide 130 or tuning segment, which may serve optical phase control as described in the draft's explanation of cavity optical thickness control. Whereas the DFB segment 116 may include grating-based DBRs s 132 and 134, and a cavity 136, aligning with various DFB laser implementations disclosed herein. The external-passive-cavity DFB laser 110 may also include active waveguide 138, which may include a gain medium such as InGaAs, and anti-reflective coatings 140 and 142. External-passive-cavity DFB laser 110 is driven by modulated input power 150, which usually comprises electrical current, resulting in modulated output power 152 and/or 154.

FIG. 1B illustrates laser emission spectra 160 showing the narrowing of the wavelength difference with increasing temperature between the dominant DFB emission 162 and emission 164 that involves the passive cavity. Specifically, the spectra 160 illustrates optical output power versus wavelength for the same device operated at 20° C. (44 mA), 50° C. (54 mA), and 70° C. (63 mA), plotted across the 1296-1312 nm wavelength range. As seen, the presence of distinct spectral peaks at each temperature corresponds to the two-mode coupled-cavity behavior, where resonance wavelengths shift with thermally induced refractive-index changes. While the slight wavelength shifting is not consequential, their separation also becomes smaller at higher temperature, thereby decreasing the PPR frequency significantly. The increase in emission wavelength is stronger for emission 162 than for emission 164, which causes the decrease the PPR frequency. The emission spectra 160 thus demonstrates PPR-frequency instability and wavelength tuning behavior across temperature-dependent operating currents for the external-passive-cavity DFB laser 110. Based on wavelength measurements the PPR frequencies are 47.8 GHz, 31.6 GHZ, and 21 GHz at 20° C., 50° C. and 70° C., respectively.

FIG. 1C represents small-signal modulation-response curves 170 for external-passive-cavity DFB 110, measured at 20° C., 50° C., and 70° C., driven at respective currents of 44 mA, 54 mA, and 63 mA, showing respective-3 dB modulation-response frequencies of 56.4 GHz, 42.1 GHz and 32 GHz. Specifically, the published external-passive-cavity DFB laser 110 is not suitable for high-speed over the usual range of operating temperatures.

FIGS. 1D-1G illustrate eye diagrams 180-186 of the laser image testing while employing various combinations of speed (Gbps) and temperature (centigrades).

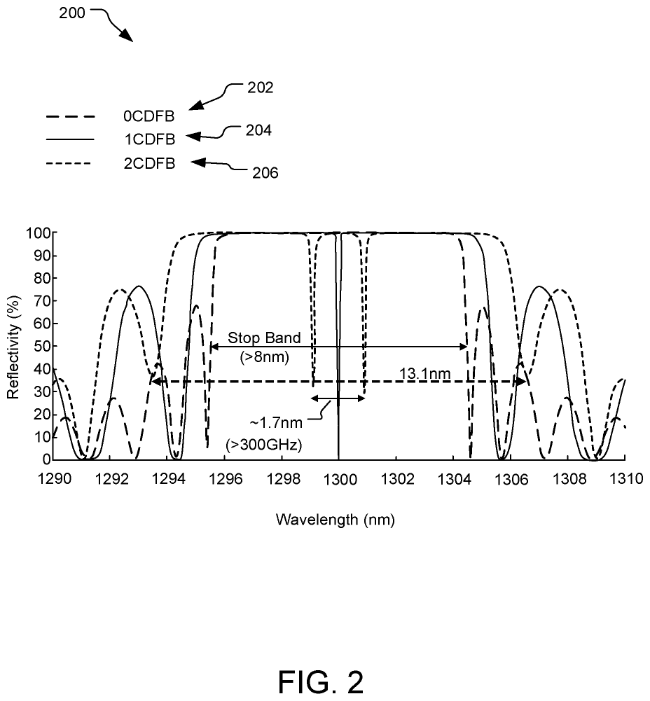

FIG. 2 illustrates reflectance spectra 200 of three (3) different DFB structures. The spectrum 202 represents a reflectance spectrum of a classic DFB laser including a nominally periodic structure of regions with slightly different effective refractive indices, each region being nominally one-quarter-wavelength thick. It is basically an active DBR. The “stop band” or wavelength extent of high reflectance is >8 nm wide, and there are no reflectance “dips” in that region. Since there are no disruptions in the periodicity, there is no “cavity” or “spacer.” The device lases at a wavelength that lines up with one or the other edges of the stop band. Herein this is referred to a “zero-cavity DFB” or 0CDFB.

The spectrum 204 represents a reflectance spectrum of a phase-shifted DFB laser herein referred to as a “1-cavity DFB” or 1CDFB, comprising 2 DBRs with a cavity within which lases at a wavelength at the cavity resonance coinciding with the sharp dip in reflectance in the center of the stop band. The thickness of a cavity is usually very close to an integral multiple of half-waves. Finally, the spectrum 206 represents a reflectance spectrum of a two-cavity DFB″ herein referred to as 2CDFB. With further introduction of a second cavity (and an intercavity DBR between the cavities) within the structure creates two resonances, coinciding with the two sharp dips in the reflectance. The wavelengths of those resonances are the wavelengths at which the “two-cavity DFB” or 2CDFB may lase. For this example, the two resonances are separated by ~1.7 nm, corresponding to ~300 GHz. The progression may be extended further, with the number of resonances matching the number of cavities. For VCSELs, the reflectance spectra are similar, and the same progression occurs from 1-cavity to 2-cavity VCSELs and higher numbers of cavities.

For simplicity, the multiple-cavity implementations disclosed herein use two (2) cavities (2CDFB and 2CVCSEL). Such two (2) cavity implementations may have only a single PPR resonance. Also, these two (2) cavity implementations may use only two materials or they may comprise any number of materials. For example, the modeled 940 nm 2CVCSEL uses GaAs and AlAs, which comprise the primary materials of most VCSELs. The substrate is GaAs, as is the incident medium. For the 1300 nm 2CDFB, the base material may be InGaAs, for which the effective refractive index is modified slightly, for example by etching regions in which part of the light energy is more present in air or another lower-refractive-index material. The effective refractive index of the InGaAs is reduced by 2% or 1% in those regions. These two designs maybe referred to herein as 2CDFB-m02 and 2CDFB-m01, respectively. In practice for DFB lasers, the differences in effective refractive indices are much lower, e.g. 0.05% to 0.5%, but the principles are the same, and the higher differences are more useful for illustrating the principles. The 2-material versions treated here are for simplicity, while not changing the fundamental behavior properties.

The results readily apply to other conditions, e.g. air as the incident medium, and/or use of dielectrics and/or metals. Dielectrics and/or metals in the structure can significantly reduce cavity-response times and aid manufacturability. The refractive indices used are approximate, which affect the number of layers required (or optimally desired). Unlike the previous implementations of DFB laser 3 which combined with an integrated passive external cavity, the two having separately defined resonant frequencies which tune differently with temperature, the multi-cavity DFBs and VCSELs herein produce both resonances in identical or closely similar materials and in the same space. Thus, the resonances should tune their resonant frequencies together at essentially the same rate, and the variation of the PPR frequency over commercial ranges of temperature should be negligible.

The term “cavity” used herein, refers to a region whose nominal thickness is an integral multiple of a half-wave, e.g. the 2-wave-thick cavities in the DFB base design are each (4 times a half-wave) thick. The cavity may include substructures, such as quantum wells with barriers, graded regions, or other features. It is possible for a delineated region to be of a thickness not equal to the nominal thickness and be compensated by other layers, e.g. the region being thicker than nominal, but surrounded by layers that are thinner than nominal. The term “cavity” herein includes regions wherein a region functions similarly to having a nominal-thickness region.

The base designs take data rates already at or near standardization (>200 Gb/s for DFBs and >100 Gb/s for VCSELs), and target data rates 2 steps above those for the higher-data-rate standards, i.e. 896 Gb/s and 448 Gb/s, respectively and both with PAM4 modulation. Many reports of PPR enhancement also show a strong small-signal relaxation oscillation frequency (ROF) resonance (also termed carrier-photon resonance, or CPR), with another peak at the PPR frequency which is usually higher than the ROF. If either peak is within the MBF, a very-strong modulation resonance may greatly distort the large-signal response of actual data modulation and also make it unsuitable for implementing PAM4 modulation. Modestly peaked ROF peaks at less than the MBF are often utilized. For strongly peaked PPR, it may be desirable for the PPR frequency, to exceed the MBF by a significant amount. The base designs herein target PPR frequencies ~300 GHz for DFBs and ~150 GHz for VCSELs, for MBFs of 224 GHz and 112 GHz, respectively, and exhibit high sensitivity to the PPR frequency. For broad PPR peaks, the PPR frequency would be closer to, and possibly lower than the MBF, and is likely to be less sensitive to the PPR frequency.

The optical frequency v is related to wavelength λ by v=c/2, where c is the speed of light, or ~300 μm/ps. Thus at 0.940 μm (1.300 μm), the optical frequency is 319 THz (230.77 THz). For small differences, the wavelength/frequencies are related by equation 1 as presented below:

$$\frac{Δ λ}{λ} = \frac{Δ v}{v} or Δ v = \frac{v}{λ} Δ λ \qquad ( 1 )$$

Here, At 940 nm, the frequency difference in GHz is Δv=339*Δλ; at 1300 nm, Δv=177.5*Δλ.

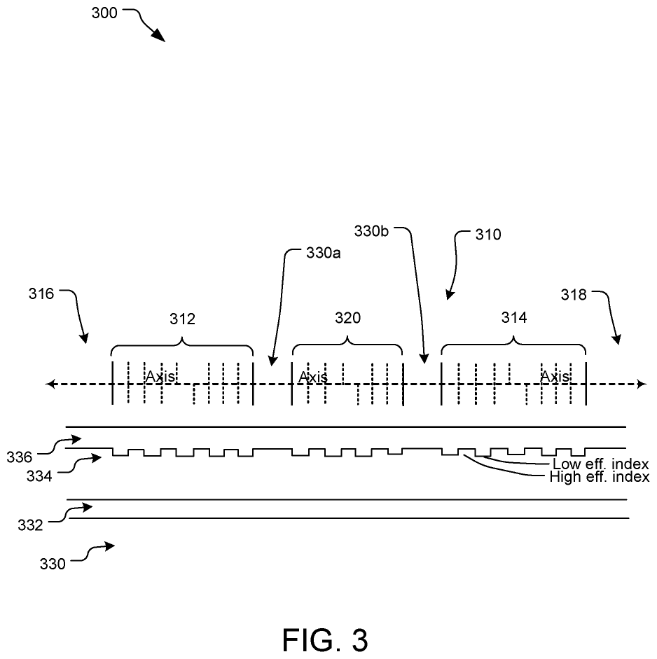

FIG. 3 illustrates a side view of a base structure of a laser 300 with two cavity DFB structure. In the initial base structure, the 2 materials both comprise InGaAs, wherein a high-effective-index (H) material, and a low-effective-index (L) “layer” have lesser and greater penetration into the 2nd cladding Layer. The layer (layer 1) is the lower-effective-index (L) material at the leftmost end of DBR 312. The first cavity is “layer” 256 (after the 255 layers in the first outer DBR 312), the second cavity is layer 476, and the last layer is layer 731 at the rightmost end of second outer DBR 314. This is a 2-cavity DFB, termed as 2CDFB-m02-256,746,731, due to its having layer 256 as the 1st cavity, layer 474 as the 2nd cavity, and 731 being the last layer. The “m02” means that the L material has an effective refractive index 2% lower than that of the H material. This is a higher index difference than most DFBs, but the cavity behavior is valid for materials having a smaller index difference. Another example is described that has a 1% index difference.

Specifically, FIG. 3 illustrates an initial base structure of a laser 300 of 2CDFB-m02-256,746,731. The base structure includes a first outer DBR 312, a first cavity 330a, a first intercavity DBR 320, a second cavity 330b, and a second outer DBR 314. These regions are oriented longitudinally along an axis. In one implementation, these regions may be formed on a substrate 330 made of InP, a first cladding layer 332 made of AlInGaAs, a waveguiding active layer 334, and a second cladding layer 336 made of AlInGaAs. The waveguiding active layer 334 may be made of alternative sections of low effective index and high effective index. Specifically, The waveguiding active layer 334 is active because light is often generated within this layer. The waveguiding active layer 334 has a high refractive index and has cladding layers 336 and 332 above and below which have lower refractive indices. The DBR regions 312, 314, and 320 are produced by modifications in the active layer and/or in one or both cladding layers and/or other surrounding materials. The modulation may be produced by etching the waveguiding active layer 334.

When used for optical communications, the laser 300 is provided with modulated input power 310 which is modulated between higher and lower powers. The input power 310 is usually electrical, but it could also be optical. In response to the modulated input power 310 the laser's output power 316, 318 is also modulated, usually at the same frequency as that of the modulated input power 310. However, the modulated output light characteristics (e.g. power, contrast between high- and low-levels) of the output power 316, 318 may depend on the properties of the laser structure, the active material (usually a semiconductor), the electronics that deliver the modulated input power to the active material, and other characteristics. In some cases, the modulated output power 316, 318 may exhibit little or no power modulation.

In other implementations, additional cavities and intercavity DBRs may be added, which increases optical complexity and possibly performance. DFBs may have 1- 2- and 3-cavities. As referred herein, a “wave” is the vacuum wavelength λ divided by the refractive index n of the material through which the light propagates. A “full-wave optical thickness” (FWOT) is λ/n. A “half-wave spacer” is λ/2n thick. A “quarter-wave” DBR layer is λ/4n thick.

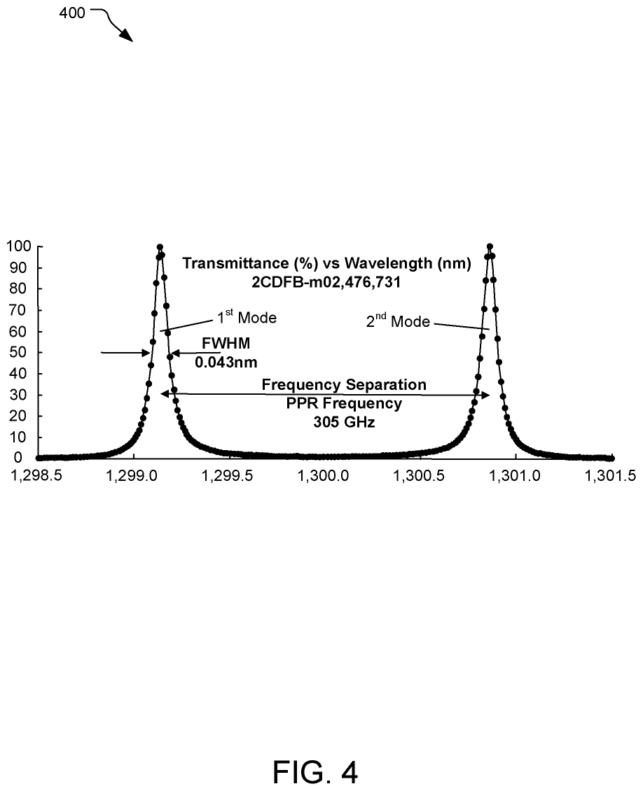

FIG. 4 illustrates a graph 400 of transmittance vs wavelength for the two cavity DFB structure illustrated in FIG. 3. Specifically, the graph 400 shows the transmittance vs wavelength of a 2CDFB-m02-256,476,731, which has 2 peaks, at 1299.14 nm and 1300.86 nm, each corresponding to a longitudinal mode. The separation of 1.72 nm, corresponds to a peak frequency difference of 305 GHz, per the target. Each peak is also characterized by the resonance linewidth, which is the full-width at half maximum (FWHM). The cavity's Q-factor is the vacuum wavelength divided by the FWHM.

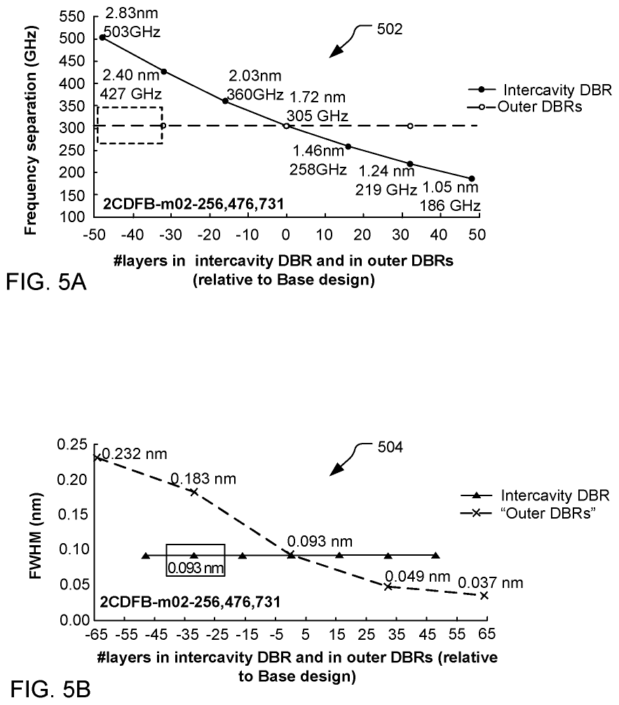

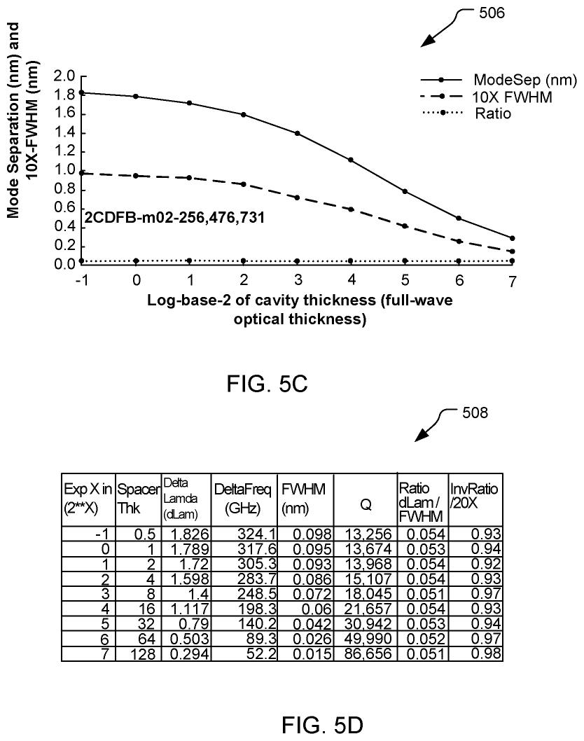

FIG. 5a illustrates a graph 502 illustrating dependences of the frequency difference (PPR frequency) of the peaks upon variations in the number of layers between the 2 cavities and in the outer mirrors. As illustrated, on the horizontal axis, 0 is the base design 2CDFB-m02-256,746,731, with 1.72 nm wavelength difference and 305 GHz PPR frequency. Subtracting 48 layers (24 pairs) between the cavities (while maintaining the nominal number of layers in the outer mirrors) is represented on the horizontal axis at −48; the peaks are separated by 2.83 nm, corresponding to a frequency difference of 503 GHz. That horizontal point at “−48” also applies to subtracting 48 layers from each of the outer DBRs while maintaining the nominal number of layers between the DBRs. The PPR frequency Av is largely dependent upon the number of quarter-wave layers in the intercavity DBR. Adding or removing layers from the outer DBRs has negligible effect on the PPR frequency, as shown in FIG. 5a. Hence, the intercavity DBR region functions as a “knob” to adjust the PPR frequency, or “Freq-Knob” for short. This behavior was used to “tune” the base design to the target PPR frequency at ~300 GHz. It is worth noting that the 503 GHz resonance feasibly allows NRZ modulation at >1Tb/s and PAM4 modulation at >2Tb/s.

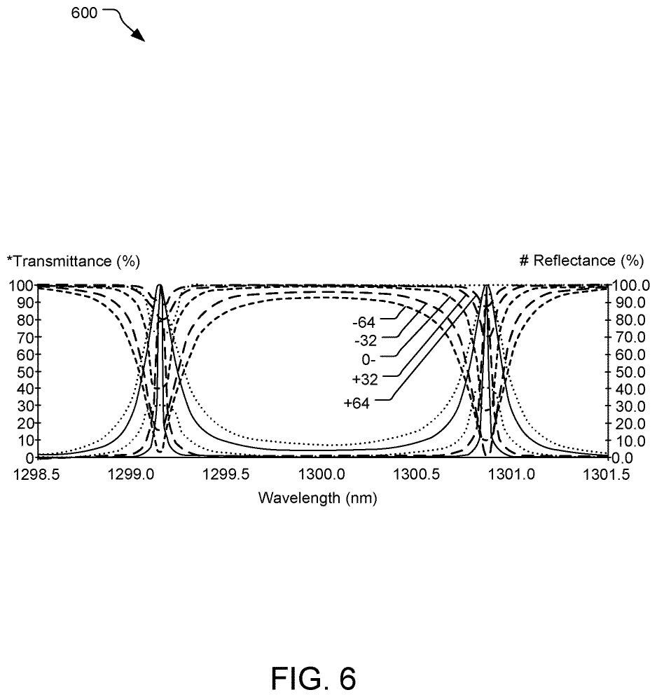

FIG. 5b is a graph 504 illustrating the relations between the peaks' FWHM and variations in the number of layers between the 2 cavities and in the outer DBRs. Specifically, as shown the peaks' FWHM is strongly dependent upon equally adding or subtracting layers from each of the outer DBRs, but is negligible when layers are added or subtracted in the intercavity region. Thus, the outer DBR regions together can be considered the “Q-Knob.” The plot in FIG. 6 of Transmittance and Reflectance corresponds to FIG. 5b, illustrating how varying the number of layers in the outer cavities affects the FWHM, but not the separation of the peaks. In these data, the added/subtracted layers are applied equally to both of the outer mirrors, e.g. at point −32, 32 layers are subtracted from each outer mirror.

FIG. 5c illustrates a graph 506 illustrating how varying the spacer thickness affects both the modal (PPR) separation and the FWHM of the peaks. Specifically, the graph 506 illustrates how varying the spacer thickness affects both the modal (PPR) separation and the FWHM of the peaks. They are affected proportionally, as the plots indicate. Throughout this variation, the ratio on FWHM to the modal separation is constant within measurement accuracy, about 0.053. FIG. 5d is table 510 illustrating the ratio of (Delta Lamda or dLam)/FWHM for various thicknesses of the cavities, corresponding to the graph in FIG. 5c.

FIG. 6 illustrates a plot 600 of transmittance and reflectance corresponding to the graph illustrated in FIG. 5b. Specifically, the graph 600 illustrates how varying the number of layers in the outer cavities affects the FWHM, but not the separation of the peaks.

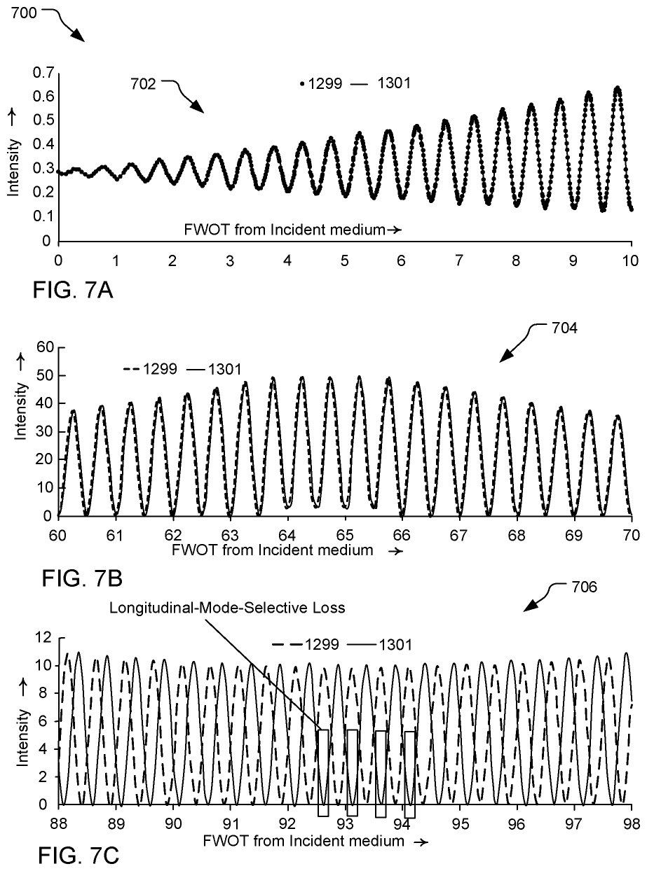

FIGS. 7a-7c illustrate graphs 700 of intensity of standing waves in three different regions of the laser cavity structure. Specifically, FIG. 7a shows intensity profile graph 702 from the incident medium into the 1st outer cavity DBR by 10 full-wave optical thicknesses (FWOT's). Intensity profiles at both the resonant wavelengths (the first mode at 1299.14 nm and the second mode at 1300.86 nm) are almost indistinguishable, showing that they are closely in phase with one another. The intensities are relatively low. FIG. 7b shows the intensities 704 at center of the 1st cavity, about 64¾ waves from the incident medium. The intensities 704 are much higher. The intensities 704 remain closely in phase but become increasingly separated toward the right (into the 1st intercavity DBR). FIG. 7c shows the intensity 706 through the middle of the 1st intercavity DBR. Here, the intensities are intermediate and are precisely out of phase at the center.

A potential issue in a light source, e.g. in optical communications, is that 2 closely equal modes can interact/compete with one another, generating noise in the signal. In a semiconductor laser, if one mode has even a slight advantage over the other, the light amplification may cause the slightly advantaged mode to dominate the intensity of the laser's output signal, exhibiting relatively low noise. However, that dominance is not necessarily stable. The dominant mode will clamp the density of “free carriers” which contribute to the optical gain, in the regions of high intensity for that mode. This phenomenon is known as “spatial hole burning.” As seen in FIGS. 7a-c, the high-intensity regions are in phase for most of the laser structure, being out-of-phase only near the center of the 1st intercavity DBR. In this region, the spatial hole burning of the dominant mode clamps its gain in its high-intensity regions (anti-nodes) but allow the carrier density in the antinodes for the non-dominating mode may exceed those in the antinodes of the dominating mode. This creates a situation wherein the initially non-dominating mode may experience higher gain than does the initially dominant mode and thus become the dominant mode. Switching between modes creates noise in the signal, which in turn creates errors in the communication link.

A means for selectively disadvantageng one of the modes is to produce an effect, which creates a loss mechanism, e.g. absorption and/or scattering and/or phase change, and/or other disruptions, in the affected region(s), in places where the intensity of one mode is near maximal and the intensity of the other is near minimal. For example, in FIG. 7c, between the horizontal axis between 93 and 93.25, the intensity is high for the 1299.14 nm (1299) mode, and low for the 1300.86 nm (1301) mode. With sufficient modal-selective loss (MSL) within that region, the 1301 nm mode is advantaged and will dominate the signal. This (MSL) approach is most effective when the modes are most-nearly 180° out of phase. This occurs at or near the center of the intercavity DBR mirror, with the phases slowly migrating away from 180° on both directions from the center. The affected regions are preferably ¼-wavelength or less wide, for this example, ~<93 nm wide.

Multiple affected regions may be utilized for increasing the MSL, especially if the affected regions are thinner, e.g. ⅛-wavelength. One means for producing such losses is patterned ion implantation, exposing those regions showing selective loss, and etching patterns into the region(s), i.e. near the center of the 1st intercavity mirror and centered near the minima of the standing waves of one mode. Implanted ions create many defect sites in semiconductors, which would absorb light inside the laser. Alternatively, regions located like those described for ion implantation may be selectively etched with patterns that may scatter and/or absorb light or otherwise create loss selectively. An etched narrow trench in the desired region may selectively disrupt one mode via reflectance, phase shift, change of interface reflectivities, or other ways, which induce MSL.

Depending on the method of current injection into the DFB laser, current may be injected to provide higher current into the high-intensity regions of the preferred mode and lower current into the other mode's high-intensity regions, thus combatting spatial hole burning with “spatial gain enhancement,” which results in modal-selective gain. A simple evaluation of MSL was performed on the base design 2CDFB-m02-256,746,731. The quarter-wave layer between 90 and 90.25 FWOT was modified in the simulation to have absorptive extinction coefficients, k, of 10⁻⁴, 10⁻³, 10⁻², and 10⁻¹. Additionally, the effects of multiple affected layers were evaluated. Results with the lowest absorption coefficient roughly correspond to modestly doped semiconductors in lasers and are nearly identical to results with zero absorption. Since the object of this procedure is to create distinction between the modes, the peak transmittances of the modes were recorded, which is strongly affected by loss.

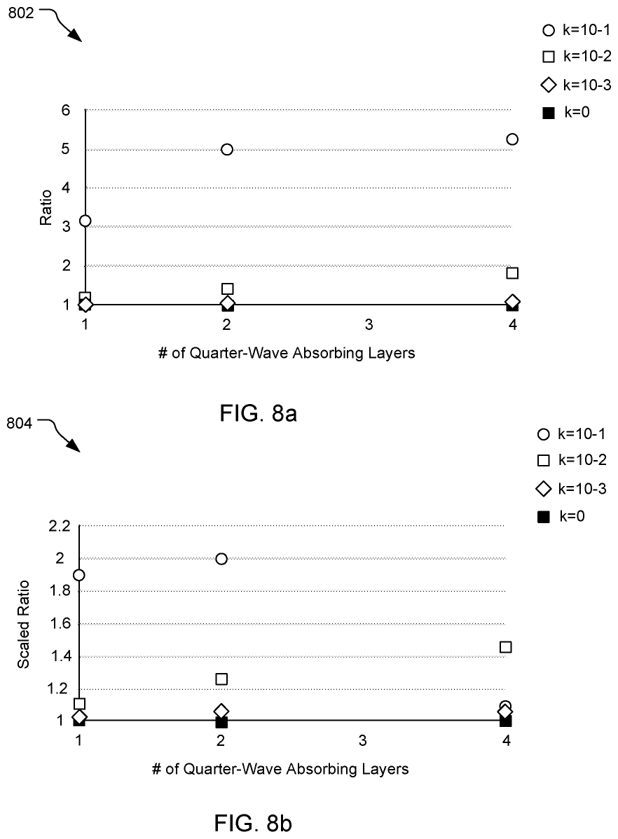

FIG. 8a illustrates a graph 802 of ratio of the peak transmittances plotted vs the number of affected layers, for each of the four extinction coefficients. While this ratio is useful, a very high ratio may be obtained with very small numbers for both, a low transmittance for the advantaged (dominant) mode may indicate a lossy and inefficient laser.

FIG. 8b illustrates a graph 804 of a scaled ratio, wherein the ratio used in FIG. 8a is multiplied by the peak transmittance of the advantaged mode. With increased absorbing layers, the scaled ratio in FIG. 8b shows a flattening or downturn, due to increasing absorption of the dominant mode. This is partly because the ¼-wave widths of the affected regions partly overlap with both modes of the standing waves. Use narrower affected areas, e.g. ⅛ wave (which is half the ¼ wave), will produce about ⅛ of the absorption on the advantaged mode, but still leave more than ½ the absorption on the disadvantaged mode. Additionally, the more regions that are affected, the farther they are from the center of the intercavity mirror, and the phases depart more from T. To optimize the scaled ratio of FIG. 8b, the MSL regions are best centered at the minima of the dominant mode, rather than at the maxima of the disadvantaged mode.

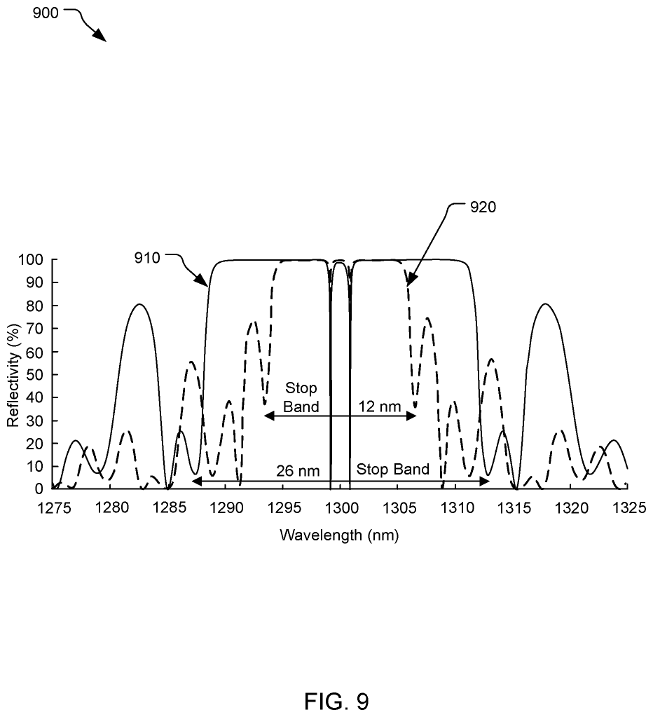

FIG. 9 illustrates a graph 900 of simulated reflectance of the base design DFB structure (solid line) 910, and a similarly-frequency-tuned structure which has a refractive-index difference between the layers of one (1) % (dashed line) 920. Specifically, the graph 900 illustrates simulated reflectance of the base design 2DFB-m02-256,476,731, and a similarly-frequency-tuned structure which has a refractive-index difference between the layers of only 1%, half that of the base structure. Therefore, it may require about twice as many layers as the base structure to achieve similar PPR frequency and FWHM (or Q). This structure is named 2CDFB-m01-512,828,1339. It is seen that the widths of the stop bands, in this case the full widths between the minima adjacent to the stop bands, are also roughly a 2:1 ratio for designs m02 and m01. While the distinction herein relates to differences in effective refractive-index, publications on DFBs relate instead to a “coupling coefficient” K. In publications, a DBR's simulated reflectance shows a stop-band width that roughly doubles with a doubling of the product |κ|L, where L is the length of the DBR. In optical terms, the stopband width is determined by the difference of refractive indices in the DBR; increasing the length of the DBR mainly makes the profile squarer at the tops. The total lengths of the DBRs for the designs “-m02” and “-m01,” including the cavities, in FIG. 9 are about 70 μm and 126 μm, respectively.

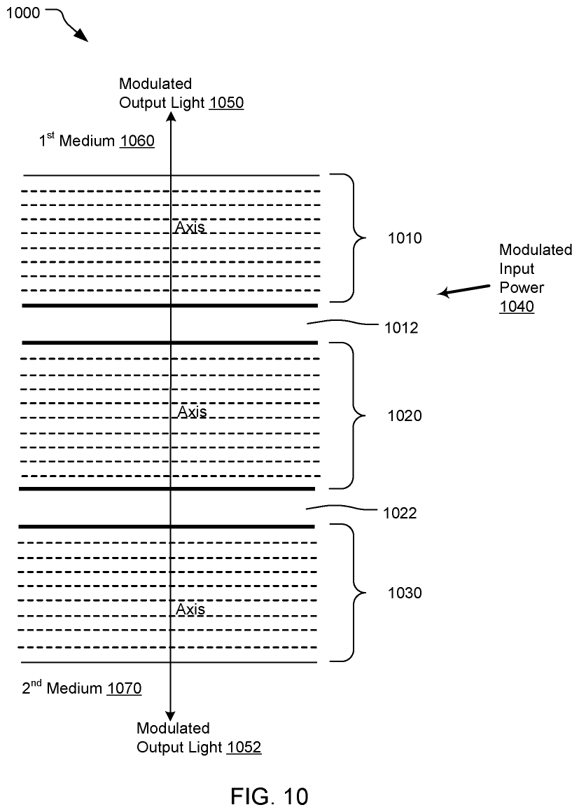

FIG. 10 illustrates a laser base structure 1000 of a VCSEL having multiple layers. The base VCSEL design is fully symmetric. The layers are all one-quarter-wavelength thick alternating between AlAs and GaAs, except for the 2 cavity layers comprising GaAs, each one-full-wavelength thick. Upon the GaAs substrate are deposited 43 quarter-wave layers, the 1st outer DBR, starting and finishing with AlAs. This followed by the 1st Cavity comprising a full-wave-thick GaAs layer, followed by the 1st Intercavity DBR comprising 59 quarter-wave-layers, the 2nd Cavity comprising a full-wave GaAs layer, and the 2nd Outer DBR comprising 43 layers, starting and finishing with AlAs. For symmetry, the incident medium is also GaAs. The structure is schematically shown in FIG. 10. It is optimized to produce a ~150 GHz PPR frequency. The total physical thickness of the layers herein is ~11 μm, more than the usual ~6-8 μm for VCSELs, but not greatly so. The number of layers (#layers) herein is likely to be more than required for an efficient fast datacom VCSEL. Depending on the shape of the PPR resonance, the target frequency may be much lower than 150 GHz, e.g. lower than 80 GHz for a 400 Gb/s 2CVCSEL, and even lower than 40 GHz for a 200 Gb/s 2CVCSEL. Lower PPR frequencies require more layers in the intercavity DBR. The output light wavelength may range from ~840 nm to well over 1060 nm, e.g. even >1300 nm. Thus, the total physical thickness of the layers may range from 8-15 μm.

Specifically, FIG. 10 illustrates the laser base structure 1000 of 2CVCSEL-940-44,104,147. The laser base structure 1000 may include a first outer DBR 1010, a first cavity 1012, an intercavity DBR 1020, a second cavity 1022, and a second DBR 1030. All these regions are oriented longitudinally along an axis. When used for optical communications, the laser base structure 1000 is provided with modulated input power 1040 which may be modulated between higher and lower powers. The modulated input power 1040 is usually electrical, but it could also be optical. In response to the modulated input power 1040 the laser base structure 1000's output power 1050, 1052 is also modulated, usually at the same frequency as that of the modulated input power 1040. However, the modulated output light characteristics (e.g. power, contrast between high- and low-levels) may depend on the properties of the laser base structure 1000, the active material (usually a semiconductor), the electronics that deliver the modulated input power 1040 to the active material, and other characteristics. In some case, the modulated output power 1050, 1052 may exhibit little or no modulation. In alternative implementations, additional cavities and intercavity DBRs may be added to the laser base structure 1000, which increases optical complexity and possibly performance. Laser base structure 1000 is bounded by a first medium 1060 and a second medium 1070, each of which comprises GaAs, for the initial simulations. Other structures analyzed herein have the first medium comprising air, and the second medium comprising a substrate, e.g. GaAs or Ge. Accordingly, the first outer DBR 1010 and first optical cavity 1012 are often referred to as the top DBR and top cavity, respectively. Similarly, second optical cavity 1022 and second outer DBR 1030 are often referred to as the bottom cavity and bottom outer DBR, respectively. Preferred embodiments of most VCSELs, including 2CVCSEls, have either modulated output light 1050 or modulated output light 1052 comprising most or all of the modulated output light, and commonly referred to as “top-emitting” or “bottom-emitting,” respectively.

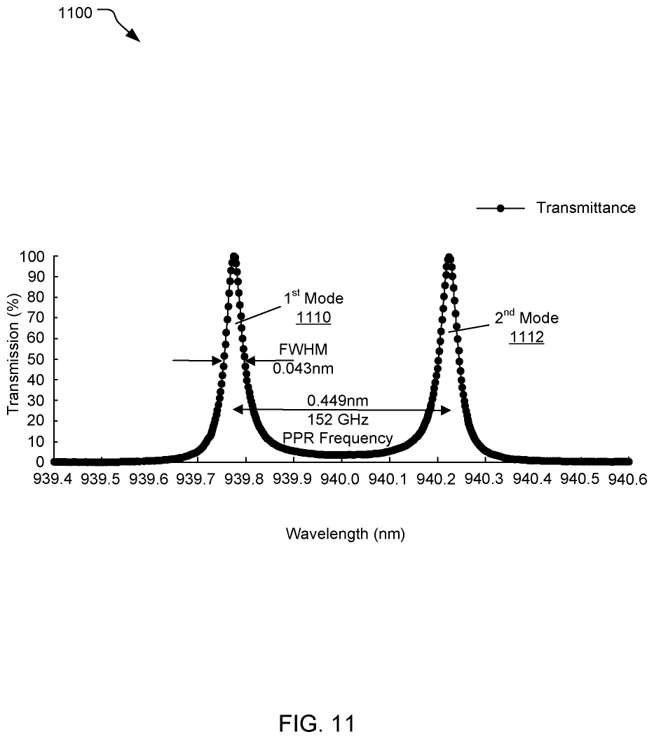

FIG. 11 illustrates transmittance spectrum 1100 for the VCSEL disclosed in FIG. 10. Specifically, the spectrum 1100 shows the transmittance spectrum for the structure, centered at 940 nm and with transmittance peaks at 939.776 nm (first mode 1110) and 940.225 nm (second mode 1112), thus the separation Δλ is 0.449 nm and the frequency difference Δv between the peaks is 152.2 GHz, per the target. Each peak is also characterized by the resonance linewidth, which is the full-width at half maximum (FWHM). The cavity's Q-factor is the vacuum wavelength divided by the FWHM.

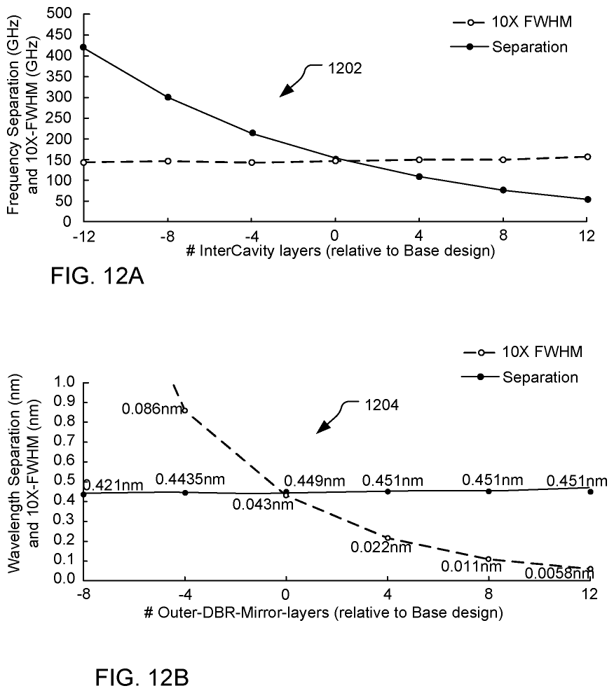

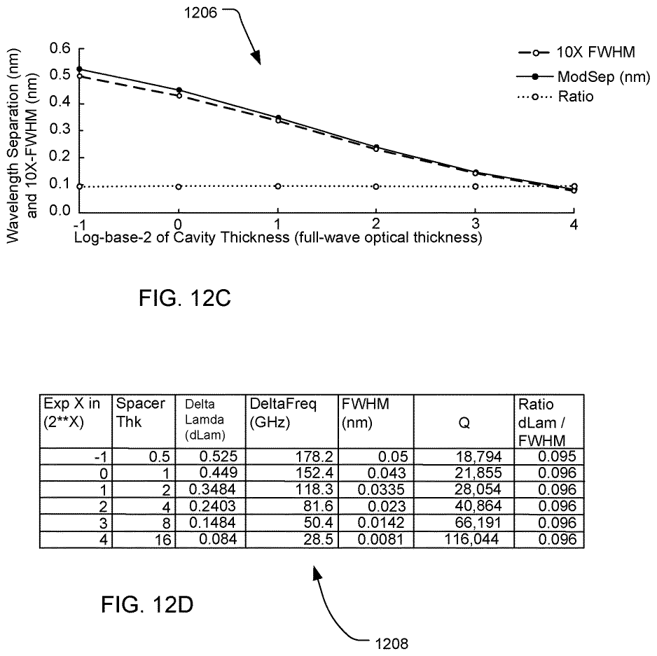

FIG. 12a illustrates a graph 1202 of frequency separation (Δv) for various number of quarter-wave layers relative to the base design. Specifically, the graph 1202 illustrates that the separation Δv strongly varies with the number of quarter-wave layers in the first intercavity DBR between the 2 cavities, Δv being smaller when the #layers is larger. Adding or subtracting those layers has negligible effect on the FWHM.

FIG. 12b illustrates a graph 1204 of wavelength separation (nm) for various number of outer DBD mirror layers relative to the base design. Specifically, the graph 1202 illustrates that Fixing the base design 59 layers in the first intercavity DBR and symmetrically adding-or-removing layers from the first and second outer mirrors, has the opposite effect. However, the effect on Δλ (or Δv) is negligible within the calculation sensitivity, but the effect on the FWHM of the transmittance peaks is strong.

FIG. 12c illustrates a graph 1206 of wavelength separation (nm) for various spacer thickness levels. Specifically, the graph 1206 shows the effect of varying the first and second cavity thicknesses identically by factors of two (2). As with the DFB laser, increasing those thicknesses decreases both the Δv and the FWHM proportionally, at a nearly constant ratio ~0.096.

FIG. 12d is a table 1208 illustrating the ratio of (Delta Lamda or dLam)/FWHM for various thicknesses of the cavities, corresponding to the graph in FIG. 12c.

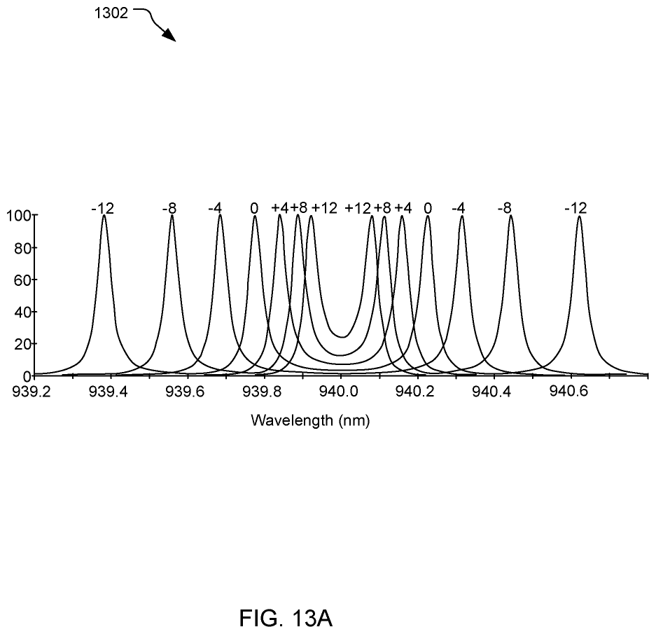

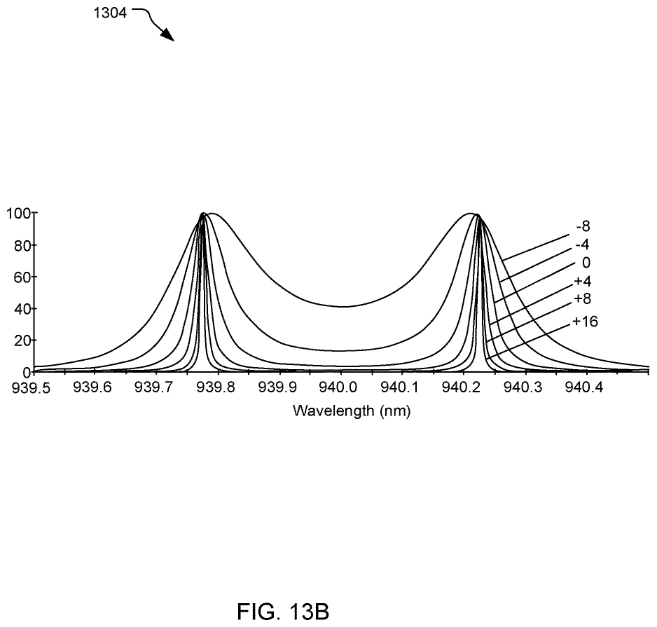

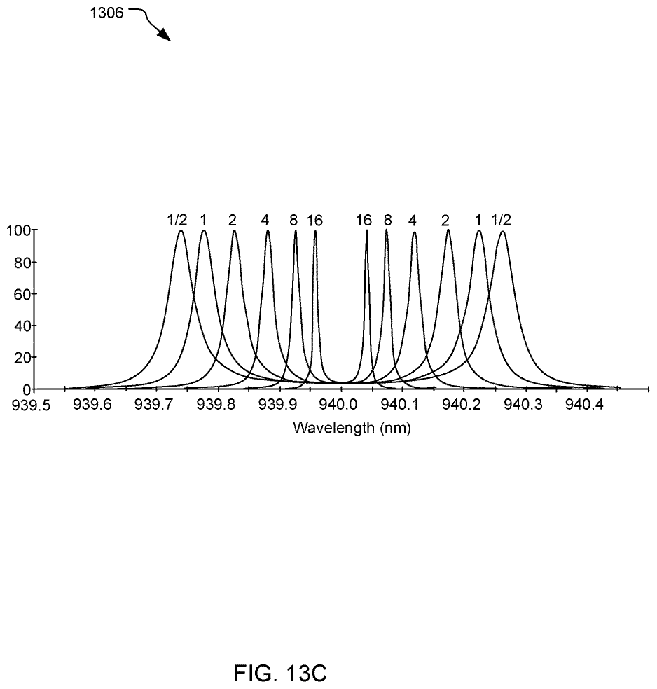

FIGS. 13a-13c illustrate direct transmittance spectra 1302-1306 corresponding to the plotted data of FIGS. 12a-c. Specifically, FIG. 13a shows overlaid plots corresponding to FIG. 12a. As illustrated, increasing layers in the 1st Intercavity DBR brings the 2 peaks toward each other, decreasing the Separation. Where the peaks are close, the peak shapes are distorted, which slightly increases the FWHM's.

FIG. 13b shows overlaid plots corresponding to FIG. 12b. As illustrated, decreasing layers in the Outer DBRs increases the FWHM. Where the FWHM is large, the peak shapes are distorted bringing the 2 peaks slightly toward each other, and in turn, disproportionally decreases the separations.

FIG. 13c shows overlaid plots corresponding to FIG. 12c. As illustrated, increasing thicknesses of the Cavities brings the 2 peaks toward each other. Both the FWHM and the separations are decreased.

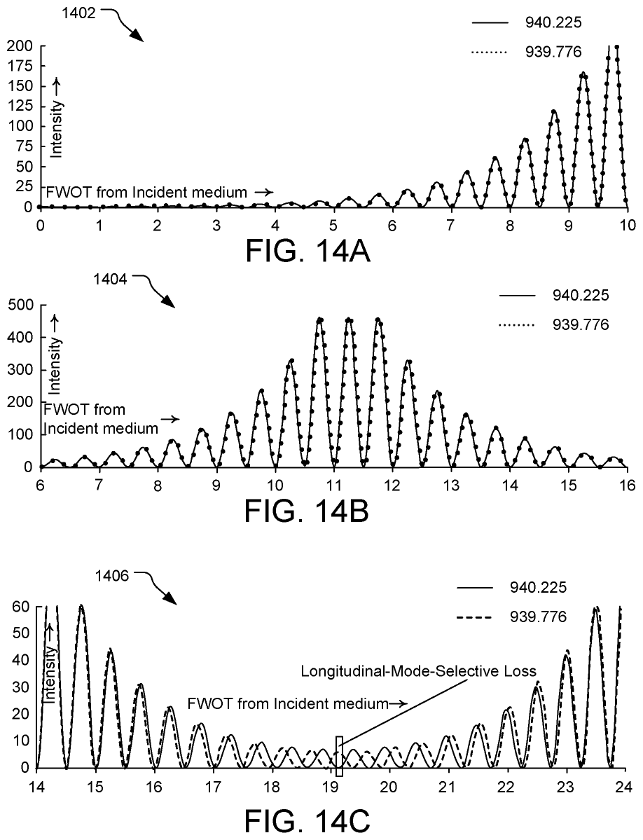

FIGS. 14a-14c illustrate intensity profiles 1402-1406 in three (3) regions for two different modes, the first mode at 939.776 nm and the second mode at 940.225 nm. Specifically, FIG. 14a illustrates the field intensity over thickness (in FWOT) adjacent to the incident medium. As illustrated, the intensity quickly increases from the initial ~0.3 to >200 (V/m)2, in less than 10 FWOT from the incident medium. The two modes are in phase; hence they are hardly distinguishable. FIG. 14b illustrates the intensity around the first cavity. As illustrated, the 3 peaks at highest intensity, are centered on the full-wave-thick first cavity layer and have peak intensities >450. In a VCSEL, the active region often resides in the middle of the full-wave-thick 1st cavity, which is centered with the middle intensity peak, about 11¼ waves from the incident medium. The 2 modes thus receive equal gain in the thin active region. The modes remain in phase and of equal intensities through the first outer DBR, and through the first cavity, but then the phases start to separate in the first intercavity DBR. Finally, FIG. 14c illustrates the center region of the first intercavity DBR. As illustrated, at the very center, the two modes are exactly out of phase. Due to the symmetry and absence of losses (e.g. absorption, scattering), the intensity profile in the 2nd cavity and 2nd outer mirror are symmetric to those in FIGS. 14a and 14b.

As with the 2CDFB, mode competition may introduce noise. High-speed VCSELs, including the 2CVCSEL, do not incur spatial hole burning due to the gain region being confined to less than a quarter-wave thickness. Additionally, in the 2CVCSEL, the two modes' intensities are in phase where the gain is present inside the cavity layer(s). It is likely that one of the longitudinal modes will dominate the laser emission, e.g. the shorter-wavelength mode which is likely to have slightly higher gain due to being slightly closer to the gain peak. However, this slight advantage may not sufficiently to decrease noise due to mode competition. As in the 2CDFB, mode stability may be enhanced, and noise reduced, by introducing longitudinal-mode-selective loss (MSL) (e.g. by absorption, scattering, phase disruption, etc.) near the center of the intercavity DBR, where the intensity profiles of the 2 modes are out of phase, as shown in FIG. 14c, at just over 19 FWOT's from the incident medium. The center of the 1st intercavity DBR lies ~4-7 μm below the surface, and the desired ~quarter-wave thickness or less, makes ion implantation unsuitable. Since the VCSEL layers are deposited epitaxially, it is straightforward to precisely deposit a thin absorbing layer or layers.

Furthermore, FIG. 14c also shows that the intensity profiles of the two modes quickly depart from being exactly out of phase. Thus, it may be preferable for the MSL to occur in just one layer. As with the 2CDFB, here a simulation was performed wherein the ¼-wave-thick MSL layer at the center of the first intercavity DBR (layer 74) was characterized with absorption extinction coefficients of k=10⁻⁴, 10⁻³, 10⁻², and 10⁻¹.

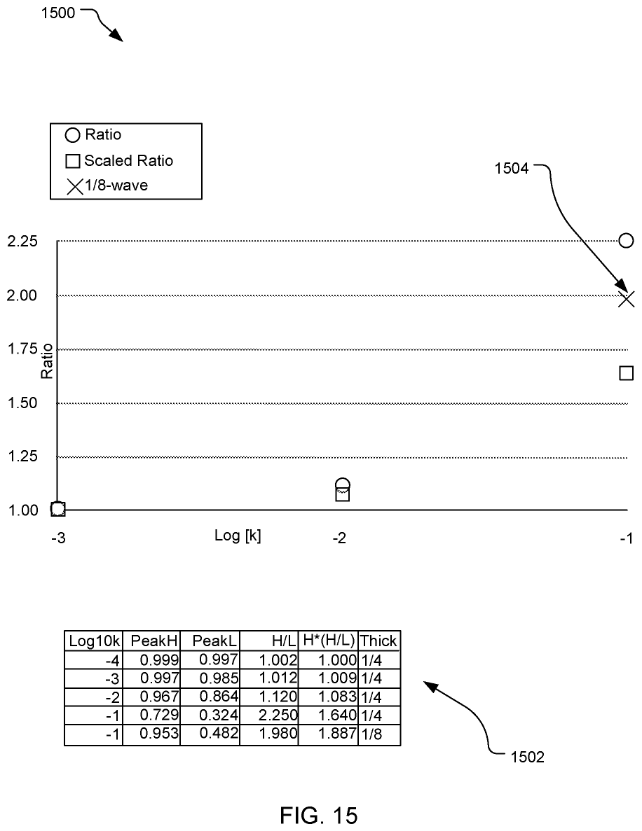

FIG. 15 illustrates results 1500 of ratio of mode peak transmittance vs log 10 [k] in layer 74 for an example CVCSEL. Specifically, the results 1500 shows that for k=10⁻⁴ and k=10⁻³, the effect was very small. At k=10⁻³, the effect was appreciable and possibly sufficient for modal stability. At k=10⁻¹, the effect was strong, but the dominant-mode's peak transmittance is <73%, indicating significant absorption, which decreases laser efficiency. Thus a “scaled ratio” is introduced, which is the ratio of mode peak transmittances (H/L) multiplied by the transmittance of the advantaged (dominant) mode (H), i.e. H*(H/L) A thinner lossy layer, e.g. ⅛-wave thick, may provide significant MSL to one mode, while better preserving lasing efficiency for the dominant mode. This effect is illustrated in FIG. 15 by the data at the bottom of the table 1502, and with the scaled ratio for the ⅛-wave-thick MSL indicated by the X-shaped marker 1504 on the plot.

As illustrated, the peak transmittance for the dominant mode was >95%, compared to <73%. An extinction coefficient k=10⁻¹ is about equal to that of a bulk semiconductor (e.g. GaAs, InGaAs) above bandgap (shorter wavelength than the absorption edge). The ⅛-wave absorbing layer is only ~33 nm thick, which is like a thin bulk material or a thin quantum well. For the 940 nm 2CVCSEL, this absorbing layer may comprise ~1-5 InGaAs quantum wells that absorb at and well beyond 940 nm, e.g. 980 nm or longer. In an 850 nm 2CVCSEL, the absorbing layer may comprise bulk or quantum-well GaAs.

Multiple-cavity devices like those described herein may be very sensitive to the uniformity of the layers' optical thicknesses, e.g. quarter-wave optical thickness in the DBRs and integral-multiples of half-wave optical thicknesses in the cavities. A constant change of optical thicknesses occurring throughout all the layers in such a device, e.g. by a constant calibration error, will mainly increase or decrease the output wavelength with little effect on performances. However, non-constant longitudinal-thickness changes, e.g. by varying calibration errors that are abrupt or slowly drifting, or by temperature changes when disparate materials like semiconductors and dielectrics are used, may render a device unuseable.

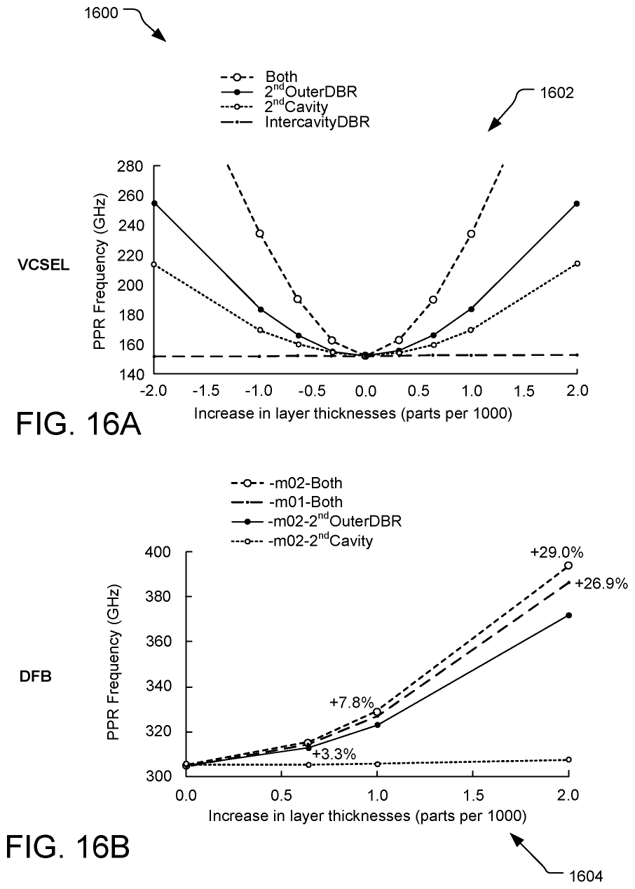

To test the sensitivities of both of the designs, simple variations on the designs were performed on each of the base designs of the 2CVCSEL and the 2CDFB: (1) slightly vary the optical thicknesses of all the Intercavity-DBR layers; (2) slightly vary the optical thickness of the 2nd-Cavity; (3) slightly vary the optical thicknesses of all the 2nd-Outer-DBR layers; and (4) slightly vary the both optical thickness of the 2nd-Cavity and the optical thicknesses of all the 2nd Outer-Cavity layers. Including the base designs, the thicknesses in both simulations were decreased and increased by 0%, 0.032% 0.064%, 0.1%, and 0.2%. The results of these tests for 2CVCSEL are disclosed in FIG. 16a and the results of these tests for 2CDFB are disclosed in FIG. 16b.

Specifically, FIG. 16a illustrates a graph 1602 showing dependence of the frequency separation (GHz) on slight changes in layer optical thicknesses for 2CVCSEL. Here the difference in mode-peak frequencies is symmetric with respect to slight increasing/decreasing the layer optical thicknesses. When a 0.1% increase OR decrease is applied to both layer groups of: 1) the 2nd Cavity, and 2) the 2nd Outer DBR, the frequency separation increases from the nominal 152 GHz to 234 GHz, which are both well above the targeted MBF of 112 GHz. The +0.1% change produces a significant variance in performance from the base design, suggesting a desire to keep the nonuniformity for 2CVCSELs below ~0.1%, though changes >0.1% may be acceptable, depending on the specifications, which depend significantly on the sharpness of the PPR peak. The examples described herein are based on a strong and narrow PPR peak which may exacerbate the sensitivity. That sensitivity does not apply quantitatively to constant changes in layer optical thicknesses in the intercavity DBR. FIG. 16a shows no visible change in PPR frequency for changes of −0.2% and +0.2%, indicating changes on the order of 1.0% (10 parts per thousand) may be acceptable, and well above that amount may be acceptable for a broader PPR peak.

FIG. 16b illustrates a graph 1604 showing dependence of the frequency separation (GHz) on slight changes in layer optical thicknesses for a CDFB. As seen in graph 1604, the 2CDFB dependencies on the same slight changes are much reduced compared to those of the 2CVCSEL. They appear acceptable with 0.2% nonuniformity, and significantly above that.

An actual 2CVCSEL may likely pump only one of the first and second-cavity layers, whichever one is most practical from fabrication/operation considerations, e.g. the first cavity layer, which is closer to the “top,” where processing would closely match present-day processing. It is likely that one of the longitudinal modes will dominate the laser emission, e.g. the shorter-wavelength mode which is likely to have slightly higher gain due to being slightly closer to the gain peak.

Temperature affects the refractive indices of essentially all materials, and strongly in the semiconductor materials often used in the materials herein. A temperature change of ~30° K changes the refractive indices of those semiconductors by about 0.2%, which is one of the values used for FIG. 16A (second cavity). In standard single-cavity VCSELs and in 2CVCSELs, the electrical pump current is exchanged in a narrow (e.g. <¼-wave) p-i-n junction (junction), wherein the heat generated may raise the junction temperature by ~30° K above that of the distant regions. For present high-speed VCSELs, the operational current range is roughly 6-9 mA. If the temperature differential is ~30° K at 9 mA, it would be ~20° K at 6 mA. This ~30° K temperature differential is roughly the same over the ambient temperature range of a VCSEL, which could range from <20° C. to over 90° C. The ambient-temperature changes affect all the layers in the device about equally, resulting in a shift of wavelength, and the usual effects on performances, such as optical gain and modulation bandwidth, but with very minor changes in the PPR frequencies. In a high-speed 2CVCSEL under operation, the current will be injected into at least one junction within at least one cavity, e.g. the cavity nearest the “topmost” surface, which is most desired for processing. Junctions are typically p-i-n junctions or buried heterojunctions. In the region(s) of such junction(s) (“junction regions”), the temperature is hottest and decreases with distance from the junction. Changes in refractive indices (and thus the optical thicknesses), relative to the surrounding areas may distort the laser performance and increase the separation of the resonant peaks and thus increase the PPR frequency. To optimize the laser's performance, use of an estimated/calculated temperature may be used to decrease the thicknesses of layers from their nominally designed thicknesses. For example, if a certain layer is expected, under typical operation, to experience a ~30° K temperature higher that of distant layers, the layer's thickness may be targeted to be ~0.2% thinner than that of nominally-identical-thickness layers far from said certain layer (distant layers). Subsequently, said certain layer, under laser operation, will have an optical thickness closer to the optical thicknesses of most of the other layers, and the laser will perform more optimally. This adjustment is best when applied individually to all layers having a significant temperature difference than distant layers that are closer to the ambient temperature. Those heated layers may extend outside the cavity and still benefit from physical-thickness-based temperature compensation In this case a “significant temperature difference” may be ~1K, or even ~0.1K. It is to be understood that these thickness and temperatures and temperature-dependences of refractive indices are examples; the numbers are dependent upon materials' optical properties, electrical input current density, laser efficiency. Different numbers may be applied similarly to the example herein. It is to be understood that the junction(s) and at least some heated layers reside in a cavity and comprise part of an architectural-PPR-frequency-tuning element. Thus varying the current within the operational current range may actively “fine-tune” the cavity temperature over a range of ~10° K, corresponding to PPR frequency tuning range that corresponds to an “increase” (or “detuning”) range of roughly 0.64 parts per 1000, per FIG. 16A. Such tuning may be applied to one or both cavities. When both cavities are actively pumped with current, one of the cavities may operate outside the operating current range.

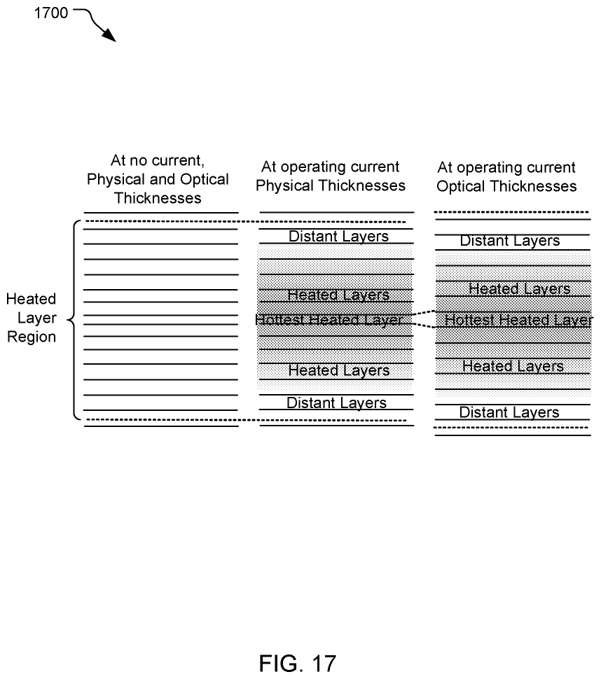

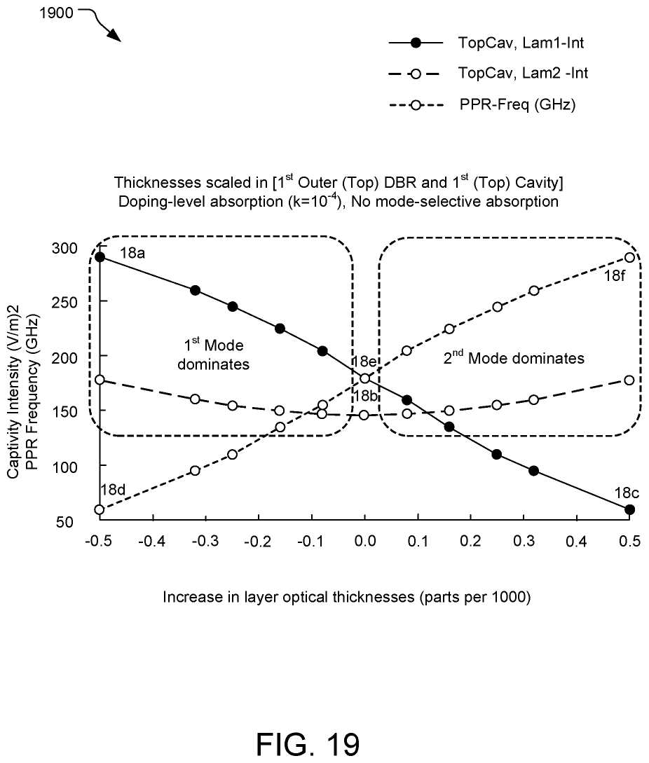

FIG. 17 qualitatively illustrates operational temperature profile, physical and optical thicknesses 1700 of various cavity regions at zero and operational current levels. As shown herein, with no current applied the layers are thinnest in the middle of the heated-layer region and increase thickness further from the middle. At operating current level, the layers are hottest in the middle of the heated layer region, and have negligible change in the physical thickness however, the optical thicknesses of the heated layers show a slight increase, which match the optical thicknesses of the distant layers. Thusly, with no current, the PPR frequency, measured by the modal separation in a reflectance spectrum, will be much higher than desired, e.g. as for the data point in FIG. 16a, for the 2nd cavity with the “increase in layer thickness” is about −0.2 parts per 1000, with the PPR frequency about 40% higher than it is with zero optical thickness increase. Applying input current will increase the optical thicknesses of the heated layers, and thus “tune” the PPR frequency to lower values, and into regions where it is near-optimal. Those “near-optimal” regions are shown in FIG. 19.

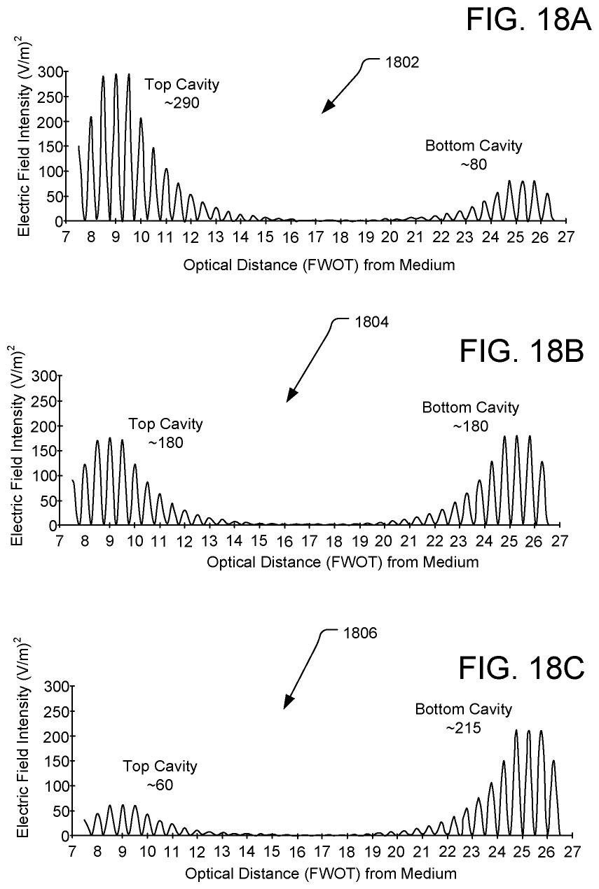

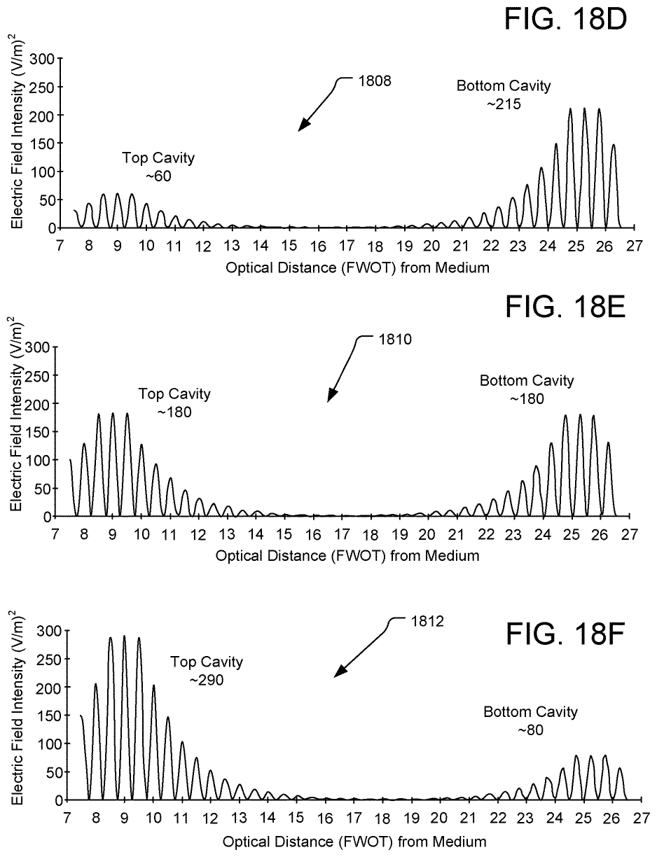

FIGS. 18a-18f illustrate graphs 1802-1812 of electric field intensity vs optical distance from the incident medium for various implementations of 2CVSEL. Specifically, each of the graphs 1802-1812 disclose electric field intensity over a range of full-wave optical thicknesses (7-27 FWOT's) from the first medium that includes both top and bottom cavities. Each graph is for either the first mode or the second mode, and for one of 3 conditions. Each condition has a different scaling of the optical thicknesses in both the Top Cavity and Top DBR from the optical thicknesses in the rest of the structure. The scaling is 1.0000 plus the increase in optical thickness. FIG. 18a plots the intensity profile for the first mode, wherein the scaling is 0.9995, meaning the thicknesses of both the Top Cavity and Top DBR are reduced by 0.0005 or 0.05% from the nominal structure. The peak intensities are ~290 (V/m)² in the Top Cavity and ~80 (V/m)² in the Bottom Cavity. FIG. 18b plots the intensity profile for the first mode, wherein the scaling is 1.0000, i.e. zero detuning. The Top and Bottom Cavities each have peak intensities ~180 (V/m)², indicating there will be mode competition and likely noise in the modulated output light. FIG. 18c plots the intensity profile for the first mode, wherein the scaling is 1.0005. The peak intensities are ~60 (V/m)² in the Top Cavity and ~215 (V/m)² in the Bottom Cavity. FIG. 18d plots the intensity profile for the second mode wherein the scaling is 0.9995. The peak intensities are ~60 (V/m)² in the Top Cavity and ~215 (V/m)² in the Bottom Cavity. FIG. 18e plots the intensity profile for the second mode in condition #5 wherein the scaling is 1.0000, i.e. zero increase. The Top and Bottom Cavities each have peak intensities ~180 (V/m)², indicating there will be mode competition and likely noise in the modulated output light. FIG. 18f plots the intensity profile for the second mode in condition #6 wherein the scaling is 1.0005. The peak intensities are ~290 (V/m)² in the Top Cavity and ~80 (V/m)² in the Bottom Cavity.

The intensity profiles in FIGS. 18a-f are achievable only by simulation, not by physical measurement. A semi-quantitative assessment of those profiles may be ascertained from reflectance spectra from the as-grown wafers. This is routinely performed for VCSELs, because it reveals the resonant wavelength and the lateral uniformity thereof over the wafer and from wafer-to-wafer. Wafers or regions of wafers may be rejected for not meeting specifications before any further expenditure of processing and testing. VCSELs are relatively insensitive to slight longitudinal nonuniformities, e.g. 0.1%. Unlike mainstream VCSELs, 2CVCSELs are sensitive to increases of plus or minus 0.01% in longitudinal uniformity, as shown in FIG. 16a and FIG. 19.

FIG. 19 illustrates a graph 1900 of peak intensities in the 1st (Top) cavity for two different modes at shorter-wavelength (first mode) and longer-wavelength (second mode), vs increases in thicknesses of the first (Top) DBR and 1st (Top) cavity in parts per 1,000, relative to the rest of the thicknesses.

Specifically, for the evaluation shown in FIG. 19 are based on 2CVCSEL-940-2,34,96,149. The design name indicates a top layer is a dielectric layer; it is one-half wave thick. The initial semiconductor layer is layer number 2 and the first-cavity layer is layer 34, meaning the first outer DBR comprises 32 layers. The second-cavity is layer 96, meaning there are 61 layers in the intercavity DBR. The final layer is layer 149, meaning there are 53 layers in the second outer DBR. Second outer DBR has many more layers and is substantially more reflective than the first outer DBR. The difference in outer DBR reflectances directs the output light almost entirely out of the first outer DBR, i.e. out the top of the 2CVCSEL, which is one preferred embodiment. For example, with a scaling of 0.99925 (minus 0.25 parts per 1,000) the intensity in the 1st (top) cavity is ~245 for the shorter-wavelength (first mode), and ~115 for the longer-wavelength (second mode) mode. The higher intensity for first mode over that of second mode indicates that the first mode will dominate the lasing in the 2CVCSEL for excitation in the 1st (top) cavity. Furthermore, the PPR resonance frequency (154.5 GHZ) is little changed (6%) from that (146.0 GHZ) of the perfectly uniform design. The PPR frequency is also plotted in FIG. 19. A preferred embodiment of the invention is a 2CVCSEL wherein only one cavity, preferably the 1st (top) cavity has optical gain. This preferred embodiment makes for processing to be almost identical to that for a single-cavity top-emitting VCSEL, and for reliability characteristics that closely with reliability data for the long-tested single-cavity top-emitting VCSELs. Importantly, the properties shown for this example straightforwardly apply to other embodiments of the invention, e.g. having gain in only the 2nd (bottom) cavity and/or back-emission through the substrate, and also for emission in either direction with both cavities having gains either uniform or independently controlled. Besides the nearby conditions shown within the graph, those favored conditions may extend outside those shown, e.g. with increases −0.001 or +0.001 (+1 part per 1000), or even much further increases, depending on the broadness of the PPR peak. Intentional physical control or tuning of these increases would be difficult due to it being sensitive to increases on the order of 0.01%, largely due to it increasing the optical thicknesses of every layer in both the top cavity and the top outer DBR. Fine detuning of the entire structure may be performed by applying increases to a smaller set of layers, as few as a single layer, or even a portion of one layer. Alternatively, or in combination with physical thickness control, fine tuning may be enacted by small changes of the input current within the operational current range.

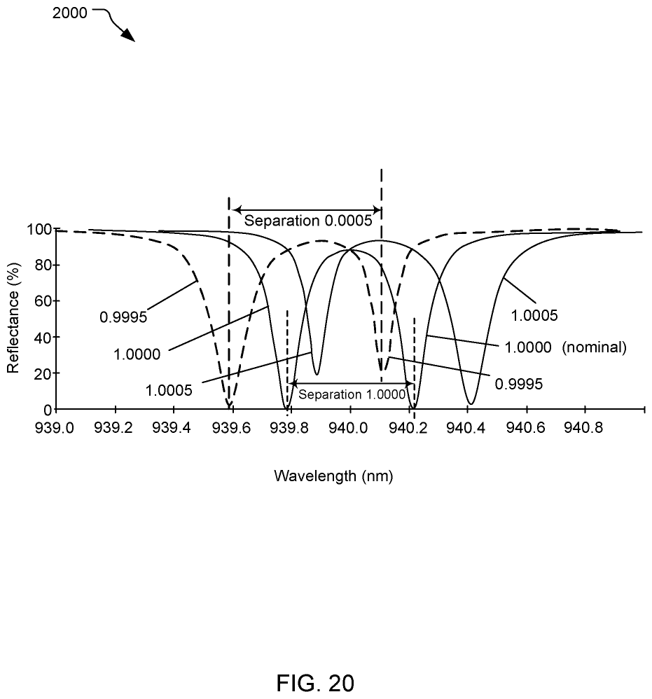

FIG. 20 illustrates a graph 2000 illustrating reflectance spectra for an implementation of a 2CVCSEL, specifically, for 2CVCSEL-940-2,34,94,147. The three reflectance spectra are for structures wherein both the first Outer (Top) DBR and the first (Top) Cavity are scaled by factors of 0.9995 and 1.0005 from the nominal design (scale 1.0000). Compared to the nominal design, the slightly-reduced-thicknesses design (scale 0.9995), show a shift to shorter wavelength (expected from the overall reduction of thicknesses), a wider wavelength (frequency) separation (as in FIG. 16a), and a reduction in the depth of the reflectance dip corresponding to the shorter-wavelength resonance, and an increase in the depth for the longer-wavelength resonance. However, for an actual produced structure, there is no reference spectrum, and the slight shift to shorter wavelength (compared to the prediction) could be caused by all the layers of the structure being slightly thinner by a fixed amount, which would not affect the device performance. Lacking a reference spectrum, the wavelength separation is ~20% wider than the design would predict, which provides an estimate a relative increase having a magnitude of ~0.05%. Additionally, the lone −0.9995 spectrum reveals the negative sign of the increase by the stronger dip for the shorter-wavelength first mode. Conversely, a positive increase is revealed by a stronger dip for the longer-wavelength second mode, as shown in FIG. 20 for the spectrum for a scaling 1.0005. A measured spectrum resembling the simulated 0.9995-scaled spectrum would then correspond to intensity profiles resembling those of FIGS. 18a and 18f, and with only the top cavity being activated, and the output power would dominantly be of the shorter-wavelength first mode. Such reflectance spectra may be used not only for qualifying wafers, but also for identifying errors in the production of the structure and applying corrections to production of a successive structure.

Correspondingly, the reflectance for the scale −1.0005 structure shows a shift to longer wavelengths, a wider wavelength (frequency) separation, and reduced dip of the longer-wavelength resonance with increased dip for the shorter-wavelength resonance. Thus, the reflectance spectrum of a wafer provides knowledge of the longitudinal thickness uniformity resonant wavelength. From this data, wafer producer learns more about their production tool's drift in wavelength during the growth process, whether it's drifting thinner or thicker, and by how much. This allows the wafer producer to adjust the tool's parameters to make a successive growth more uniform, or slightly nonuniform by a precise amount.

Here, the changes in the reflectance dips of the resonances correlate with the peak intensities in those cavities. A reduced dip in the reflectance correlates to higher intensity in the cavity. A structure that is designed for “top emission,” i.e. emitting out of the top surface of the wafer, has fewer layers (lower reflectance) in the 1st (top) DBR and more layers (higher reflectance) in the 2nd (bottom) DBR.

While this invention has been described in terms of several embodiments, there are alterations, modifications, permutations, and substitute equivalents, which fall within the scope of this invention. It should also be noted that there are many alternative ways of implementing the methods and apparatuses of the present invention. It is therefore intended that the following appended claims be interpreted as including all such alterations, modifications, permutations, and substitute equivalents as fall within the true spirit and scope of the present invention. Unless otherwise stated, all the features and properties described for 2CVCSELs or 2CDFBs may apply to both lasers.

What is claimed is:

1. A two-cavity distributed-feedback (2CDFB) laser device comprising:
a first cavity and a second cavity separated by an intercavity distributed Bragg reflector (DBR), said cavities and intercavity DBR configured as an architectural-PPR-frequency-tuning element;
a first outer DBR and a second outer DBR each configured to define a quality-factor (Q) tuning function;
the first cavity and the second cavity each having an optical thickness that is approximately an integral multiple of half-waves; and
a pair of resonances separated by a photon-photon resonance (PPR) frequency selected to enhance modulation response.

2. The device of claim 1, wherein said modulation response is enhanced to support data rates exceeding 400 Gb/s PAM4 and/or exceeding 200 Gb/s.

3. The device of claim 1, wherein the first outer DBR, the second outer DBR, and the cavities each comprise a plurality of layers for adjusting resonance linewidth without significantly adjusting the PPR frequency.

4. The device of claim 3, wherein layer pairs can be inserted or deleted in said intercavity DBR to adjust the PPR frequency without significantly changing the resonance linewidth.

5. The device of claim 1, further comprising longitudinal-mode-selective loss (MSL) elements positioned to preferentially suppress one resonant mode.

6. A two-cavity vertical-cavity surface-emitting laser (2CVCSEL) device, comprising:
a first optical cavity and a second optical cavity separated by an intercavity DBR, said cavities and intercavity DBR functioning as an architectural-PPR-frequency-tuning element;
a first outer DBR and a second outer DBR each comprising alternating high- and low-index quarter-wave layers; and
the first cavity and the second cavity each formed of GaAs-based materials and having an optical thickness of approximately an integral multiple of one half wave;
wherein the 2CVCSEL device supports two longitudinal modes, a first mode and a second mode being separated by a photon-photon resonance (PPR) frequency to enhance modulation bandwidth.

7. The 2CVCSEL device of claim 6, wherein modulation response is enhanced to support data rates exceeding 400 Gb/s PAM4 and/or exceeding 200 Gb/s NRZ.

8. The 2CVCSEL device of claim 6, wherein the first outer DBR comprises approximately 32 quarter-wave layers, the intercavity DBR comprises approximately 61 quarter-wave layers, and the second outer DBR comprises substantially more quarter-wave layers than said first outer DBR.

9. The 2CVCSEL device of claim 6, wherein the total vertical stack thickness is approximately 8-15 μm.

10. The 2CVCSEL device of claim 6, wherein the PPR mode separation corresponds to a target range of approximately 40-150 GHz at an output wavelength range of approximately 840-1330 nm.

11. The 2CVCSEL device of claim 6, wherein layer thickness variations are controlled to less than 0.2% to maintain desired optical performance.

12. The 2CVCSEL device of claim 6, wherein the optical thicknesses in the intercavity DBR differ by more than 0.1% from the optical thicknesses in said first or second cavities or the first outer DBR or the second outer DBR.

13. The 2CVCSEL device of claim 6, wherein at least one of said first and second cavities is an activated cavity, having an applied modulated electrical current within an operational current range to generate light.

14. The 2CVCSEL device of claim 13, wherein said electrical current furthermore creates heated layers in and nearby said activated cavity having temperatures higher than distant layers, wherein said heated layers have optical thicknesses substantially thinner than those of said distant layers when no current is applied, and approximately equal optical thicknesses to said distant layers when current is applied within the operational current range.

15. The 2CVCSEL device of claim 13, wherein said first outer DBR and/or said first cavity comprise layers whose optical thicknesses differ from the optical thicknesses in said second outer DBR and/or second cavity by greater than an amount sufficient to generate a higher intensity in said activated cavity for one of said first mode and said second mode, the mode having higher intensity in said activated cavity becoming a dominant mode which comprises majority of modulated output light from the 2CVCSEL device.

16. The 2CVCSEL device of claim 6, further comprising a longitudinal-mode-selective loss region positioned near middle of the intercavity DBR.

17. The 2CVCSEL device of claim 6, wherein adjustments to transmittance characteristics are obtained by adding or removing layers from the intercavity or outer DBRs.

18. The 2CVCSEL device of claim 14, wherein said electrical current furthermore in said activated cavity creates heated layers in and nearby said activated cavity having temperatures higher than distant layers, wherein said heated layers have optical thicknesses substantially varied by varying said electrical current within said operational current range, thereby actively tuning the PPR frequency to a more-desired value.

19. The 2CVCSEL device of claim 18, wherein both cavities are activated cavities, wherein one of said cavities may operate inside or outside of the operating current range.
